(19) United States
(12) Patent Application Publication
(10) Pub. No.: US 2010/0108501 A1
(43) Pub. Date: May 6, 2010

(54) MO-BASED SPUTTERING TARGET PLATE AND METHOD FOR MANUFACTURING THE SAME

(75) Inventors: Toru Inaguma, Chiba (JP); Hiroaki Sakamoto, Chiba (JP); Tadami Oishi, Tokyo (JP); Shingo Izumi, Tokyo (JP); Hajime Nakamura, Tokyo (JP)

Correspondence Address: WENDEROTH, LIND & PONACK, L.L.P., 1030 15th Street, N.W.,, Suite 400 East, Washington, DC, 20005-1503, US

(73) Assignee: NIPPON STEEL MATERIALS CO., LTD

(21) Appl. No.: 12/448,824

(22) PCT Filed: Jan. 11, 2008
(86) PCT No.: PCT/JP2008/050302

§ 371 Date: Sep. 2, 2009

(30) Foreign Application Priority Data
Jan. 12, 2007 (JP) 2007-004392

(51) Int. Cl. C23C 14/34; B22F 1/00; B22F 3/15; B21B 1/26

(52) U.S. Cl. 204/298.13; 419/23; 72/200

(57) ABSTRACT

A method for efficiently manufacturing a large-area Mo-based target plate at a high yield is provided. In the manufacturing method, the condition of the content of a trace element and the rolling condition are used in combination to reduce the deformation resistance and to suppress the occurrence of cracks such as edge cracking. The method for manufacturing an Mo-based sputtering target by rolling an Mo-based ingot includes the steps of: manufacturing the Mo-based ingot in which the oxygen concentration is controlled to 10 ppm by mass or more and 1000 ppm by mass or less; and heating and rolling the Mo-based ingot at a rolling temperature of 600° C. or more and 950° C. or less.

### TECHNICAL FIELD

The present invention relates to an Mo-based material used, for example, as an electrode material for liquid crystal devices, and in particular, to a method for manufacturing an Mo-based sputtering target plate.

### BACKGROUND ART

An Mo-based alloy is being used as an electrode material for liquid crystal devices and the like. Such an electrode is formed by a sputtering method, and therefore an Mo-based target plate for sputtering is required. In particular, with the increase in the area of liquid crystal devices, there is a demand for a target material having a large area, and attempts have been made to manufacture a large-area Mo-based target plate by rolling an Mo-based ingot used as a base material.

Non-Patent Document 1 describes a technique for rolling Mo. More specifically, with this technique, a rolled plate can be manufactured by hot-rolling at 1200 to 1370° C. after extrusion and subsequent repeated heating at 1150 to 1320° C.

Patent Document 1 relates to a method for manufacturing a metal member by rolling a core material made of a metal material having a melting point of 1800° C. or higher after the core material is covered with a covering material made of a metal material having a lower deformation resistance than the core material. In this method, the covering material is placed between a rolling roll and the core material, and the contact surface of the covering material, which comes in contact with the core material, has a maximum surface roughness (Ry) of 0.35 μm or more. In this manner, the sliding between the core material and the covering material can be suppressed during hot-rolling, so that the formation of flaws in the core material can be prevented. The range of hot-rolling temperature described in Patent Document 1 is more than 800° C. and 1350° C. or less, but no description is given of the temperature and deformation resistance during rolling.

Patent Document 2 discloses a method for manufacturing an Mo target material. This method includes: a step of compression-molding a powder composed mainly of Mo and having an average particle diameter of 20 μm or less; a step of pulverizing the molded product into a secondary powder of 10 mm or less (coarser than the raw powder); a step of performing hot isostatic pressing under the conditions of a temperature of 1000 to 1500° C. and a pressure of 100 MPa or more; and a step of performing hot-rolling a plurality of times at a temperature of 500° C. to 1500° C. and a rolling reduction ratio of 2 to 50%. The advantages of the above invention are that segregation of additional elements other than Mo due to powder aggregation can be prevented and that the deformation of the pressure sintered product can be suppressed, so that the Mo-based target material can be efficiently manufactured. However, no description is given of the concentrations of the trace elements and the deformation resistance.

In Patent Document 3, to manufacture an Mo sputtering target, an Mo sintered body with an oxygen content of 500 ppm or less is used. Patent Document 3 states that the use of such a sintered body facilitates plastic working and reduces the formation of oxide particle phase in the sputtering target material, so that the formation of particles can be suppressed. It is also stated that, by increasing the relative intensity ratio of the most close-packed (110) plane of Mo having the BCC (body centered cubic) crystal structure, the sputtering rate (deposition rate) is increased, and therefore the productivity can be improved. More specifically, it is desirable that the relative X-ray diffraction intensity ratio R₍₁₁₀₎ of the (110) plane (normalized using four major peaks) be 40% or more. In Patent Document 3, the preferred range of the rolling reduction ratio per rolling pass is 10% or less. More specifically, the above structure was obtained at a rolling reduction ratio per pass of about 4%.

Patent Document 4 discloses a pressure-sintered molybdenum target material. The molybdenum target has a fine structure with an average grain size of 10 μm or less and has a relative density of 99% or more. It is stated that such a controlled structure provides a uniform sputtered film and can reduce the number of particles in the film.

Patent Document 5 discloses a sputtering target in which the sputtering surface has a surface roughness Ra (arithmetic mean roughness) of 1 μm or less and a surface roughness Ry (maximum height) of 10 μm or less and in which the width of recesses present on the sputtering surface and having a depth of 5 μm or more is 70 μm or more measured as the distance between local peaks in a roughness curve. Patent Document 5 states that the use of such a target plate suppresses abnormal discharge that occurs at the sputtering surface. It is also stated that such a sputtering surface can be obtained by surface grinding and finishing.

As described above, in the conventional techniques, the productivity of Mo-based target materials is improved by producing a rolled plate using a combination of extrusion and hot-rolling, controlling the surface roughness of a covering material to suppress the formation of flaws during rolling, or using a secondary powder prepared by pulverizing a molded product. In a method for manufacturing an Mo-based target plate by rolling, the productivity may be improved by combining the rolling conditions with the conditions of trace element concentrations and crystal grain size to reduce the deformation resistance and by suppressing the formation of cracks and chipping. However, no such a technique has been proposed.

[Patent Document 1] Japanese Patent Application Laid-Open No. 2006-218484.

[Patent Document 2] Japanese Patent Application Laid-Open No. 2005-240160.

[Patent Document 3] Japanese Patent Application Laid-Open No. 2007-113033.

[Patent Document 4] Japanese Patent No. 3244167.

[Patent Document 5] Japanese Patent Application Laid-Open No. 2001-316808.

[Non-Patent Document 1] Special metal materials, Yoshitsugu Mishima, Corona publishing Co., Ltd., p. 95 (1961) .

### DISCLOSURE OF THE INVENTION

### Problems to be Solved by the Invention

Since the toughness of an Mo-based ingot is not sufficiently high, edge cracking and rapture frequently occur during rolling. Therefore, a high yield is difficult to attain using a manufacturing method by rolling. Moreover, the deformation resistance during compressive plastic deformation is high. Therefore, in an actual rolling process in which the ability of the rolling mill is limited, the number of passes is large, so that the productivity is low.

Accordingly, it is an object of the present invention to provide a method for efficiently manufacturing a large-area Mo-based target plate at a high yield by using specific rolling and trace element content conditions under which the deformation resistance can be reduced and the occurrence of cracks such as edge cracking can be suppressed. It is another object to provide a sputtering target material that is less likely to cause abnormal discharge during sputtering deposition and less likely to cause the formation of foreign objects such as particles in a thin film.

### Means for Solving the Problems

(1) A method for manufacturing an Mo-based sputtering target plate from an Mo-based ingot, the method comprising the successive steps of: manufacturing the Mo-based ingot in which an oxygen concentration is controlled to 10 ppm by mass or more and 1000 ppm by mass or less; and heating and rolling the Mo-based ingot at a rolling temperature of 600° C. or more and 950° C. or less.

(2) A method for manufacturing an Mo-based sputtering target plate from an Mo-based ingot, the method comprising the successive steps of: manufacturing the Mo-based ingot in which an oxygen concentration is controlled to 10 ppm by mass or more and 1000 ppm by mass or less; wrapping the Mo-based ingot with a metal plate to form a capsule and evacuating and vacuum-sealing the capsule; heating and rolling the capsule at a rolling temperature of 600° C. or more and 950° C. or less; and removing the Mo-based plate from the capsule.

(3) The method for manufacturing an Mo-based sputtering target plate according to (1) or (2), wherein, in the step of manufacturing the Mo-based ingot, an average crystal grain size of the Mo-based ingot is controlled to more than 10 μm and 50 μM or less.

(4) The method for manufacturing an Mo-based sputtering target plate according to any of (1) to (3), wherein, in the step of rolling, a rolling reduction ratio per pass is more than 10% and 50% or less, and a total rolling reduction ratio is 30% or more and 95% or less.

(5) The method for manufacturing an Mo-based sputtering target plate according to any of (1) to (3), wherein the step of rolling comprises the step of reheating the capsule at a reheating temperature of 1150° C. or more and 1250° C. or less and holding the capsule at the reheating temperature for 1 minute or more and 2 hours or less.

(6) The method for manufacturing an Mo-based sputtering target plate according to any (1) to (3), wherein the Mo-based ingot is obtained by pressure-sintering a raw Mo-based powder having a particle size of 20 μm or less by a hot isostatic pressing method.

(7) The method for manufacturing an Mo-based sputtering target plate according to (2), wherein the metal plate is a steel plate.

(8) The method for manufacturing an Mo-based sputtering target plate according to any of (1) to (3), further comprising, after the step of rolling, the step of forming a sputtering surface by mechanical surface grinding.

(9) An Mo-based sputtering target plate having an oxygen concentration of 10 ppm by mass or more and 1000 ppm by mass or less and an average crystal grain size of more than 10 μm and 50 μm or less.

(10) The Mo-based sputtering target plate according to (9), having a sputtering surface of an arithmetic mean waviness (Wa) of 0.1 μm or more and 2.0 μm or less.

### EFFECTS OF THE INVENTION

The method for manufacturing an Mo-based sputtering target plate according to the present invention is applicable to manufacturing of an Mo-based sputtering target plate by rolling. Such a manufacturing method has advantages in that the number of passes required to roll an Mo-based ingot to a predetermined thickness can be reduced and that the occurrence of edge cracking and rapture can be suppressed. Therefore, the Mo-based sputtering target plate can be efficiently manufactured. The obtained Mo-based sputtering target plate is high quality and low cost and therefore is useful as a sputtering target plate for electrode members constituting a liquid crystal device and other devices. Moreover, the Mo-based target plate of the present invention is less likely to cause abnormal discharge during sputtering deposition and less likely to cause the formation of foreign objects such as particles in a thin film.

### BEST MODE FOR CARRYING OUT THE INVENTION

A manufacturing method of the present invention mainly comprises the step of manufacturing an Mo-based ingot and the step of rolling the Mo-based ingot having been heated. The present inventors have found that, when the concentration of oxygen contained in an Mo-based ingot is controlled to fall within a specific range and the rolling temperature is also controlled to fall within a specific range, the deformation resistance during rolling is reduced to a very low level, so that the number of passes required for rolling reduction can be minimized. The inventors have also found that the occurrence of edge cracking and cracks can be very effectively suppressed under the above rolling conditions. Moreover, when the average grain size of the Mo-based ingot is controlled to fall within a specific range, the advantages described above are more preferably obtained.

Hereinafter, the present invention will be described in detail.

The present inventors have found from extensive experiments that, when the concentration of oxygen contained in an Mo-based ingot falls within the range of 10 ppm by mass or more and 1000 ppm by mass or less and the temperature during rolling deformation falls within the range of 600° C. or more and 950° C. or less, the deformation resistance of the Mo-based ingot can be significantly reduced. Moreover, when the average crystal grain size of the Mo-based ingot falls within the range of more than 10 μm and 50 μm or less, the deformation resistance of the ingot can be further reduced.

The concentration of oxygen contained in the ingot is defined as the concentration measured in an interior region at least 100 μm from the surface of the ingot. When the ingot was heated in air, oxidation occurred near the surface, so that the oxygen concentration near the surface increased. However, the increase in oxygen concentration only in a region within less than 100 μm from the surface did not change the deformation resistance and did not affect the occurrence of cracks. Accordingly, the oxygen concentration measured in an interior region at least 100 μm from the surface is regulated.

FIG. 1 shows the relationship between the average deformation resistance measured for Mo ingots heated to 800° C. and compressed and deformed by 50% and the concentration of oxygen contained in the ingots. The deformation resistance was measured for small test pieces cut from each ingot. More specifically, the deformation resistance was determined from an S—S curve measured at each deformation temperature using a working formastor testing machine. The holding time at the deformation temperature was set to 10 minutes, and the strain rate for compression deformation was set to 10/sec. The test pieces were compressed and deformed by 50%. The average deformation resistance is the average of deformation resistance at 0 to 50% deformation. The average crystal grain size of the ingots was 20 μm as measured by the line segment method.

The average deformation resistance exhibited a minimum at an oxygen concentration of about 100 to 200 ppm by mass and tended to increase when the oxygen concentration is greater and smaller than the above value. The oxygen concentration range used in the present invention is 10 ppm by mass or more and 1000 ppm by mass or less where the deformation resistance is held at a low level (400 MPa level). Amore preferred range is 14 ppm by mass or more and 600 ppm by mass or less where the deformation resistance is held at a lower level (300 MPa level).

When the oxygen concentration is less than 10 ppm by mass, the deformation resistance increases under any rolling temperature condition, so that the number of rolling passes cannot be reduced. In this case, when rolling is forcibly performed at a rolling reduction ratio per pass of more than 10%, edge cracking and cracks tend to occur during rolling. Therefore, the oxygen concentration is set to 10 ppm by mass or more. When the oxygen concentration exceeds 1000 ppm by mass, the deformation resistance increases, and the number of rolling passes increases. Also in this case, when rolling is forcibly performed at a rolling reduction ratio per pass of more than 10%, edge cracking and cracks tend to occur, and the yield is significantly reduced. Therefore, the oxygen concentration is set to 1000 ppm by mass or less. In other words, when the oxygen concentration is in the range of the present invention, i.e., 10 ppm by mass or more and 1000 ppm by mass or less, a target plate with no edge cracking and no cracks can be obtained in a small number of rolling passes by performing rolling under the condition of a rolling reduction ratio per pass of more than 10%.

FIG. 2 shows the relationship between the average deformation resistance and deformation temperature measured for ingots with controlled oxygen concentrations of 5 ppm by mass and 200 ppm by mass. In the ingot with an oxygen concentration of 5 ppm by mass, which is outside the range of the invention, the deformation resistance increased monotonically with an increase in temperature. However, in the ingot with an oxygen concentration of 200 ppm by mass, which falls within the range of the invention, the deformation resistance exhibited a minimum at about 800° C. and was held at a lower level than that of the ingot with an oxygen concentration of 5 ppm by mass in the range of 600° C. or more and 950° C. or less.

When rolling is performed in the rolling temperature range of 600° C. or more and 950° C. or less, almost no edge cracking and cracks caused by rolling occur in the Mo-based ingot. In particular, under the rolling condition of a rolling reduction ratio per pass of more than 10%, rolling can be efficiently performed at a very high yield. When the temperature of the Mo-based ingot during rolling is less than 600° C., the deformation resistance increases steeply, and edge cracking and cracks tend to occur. Therefore, the rolling temperature is set to 600° C. or more. When the rolling temperature of the Mo-based ingot during rolling exceeds 950° C., the deformation resistance also increases. Therefore, rolling is difficult to perform efficiently, and edge cracking and cracks tend to occur. Accordingly, the rolling temperature is set to 950° C. or less.

The average crystal grain size of the ingot is measured at an interior point 100 μm to 10 mm from the surface of the ingot. Preferably, this plane corresponds to the sputtering surface of a target plate obtained by machine grinding performed after the rolling step. The crystal grain boundaries are revealed by etching after the observation surface is mirror-finished by, for example, polishing. The obtained structure is measured for crystal grain size by the line segment method to determine the average crystal grain size (number average crystal grain size).

FIG. 3 shows the change in average deformation resistance at a heating temperature of 800° C. for ingots having different average crystal grain sizes. The oxygen concentration of each ingot was 100 ppm. When the average crystal grain size was greater than 10 μm, the deformation resistance was small, being at a level of 200 to 300 MPa. Therefore, in the present invention, the average crystal grain size of the ingot is preferably greater than 10 μm. When the average crystal grain size is 10 μm or less, rolling may be difficult to perform.

When the average crystal grain size exceeds 50 μm, the deformation resistance is at a low level of less than 300 MPa. However, when rolling is performed at a rolling reduction ratio per pass of greater than 10%, fine edge cracking and cracks may occur during rolling. Therefore, rolling may not be performed efficiently in some cases. Accordingly, the average crystal grain size is preferably 50 μm or less.

The average crystal grain size is more preferably in the range of greater than 10 μm and 35 μm or less. This is because, when the average crystal grain size is 35 μm or less, rolling can be performed at a lower deformation resistance, and therefore edge cracking and cracks do not occur.

In the method of the present invention, the Mo-based ingot may be wrapped with a metal plate to form a capsule. In this manner, surface oxidation during rolling and reheating can be suppressed, so that the yield of the product can be improved.

A gap may be present between the encapsulating plate and the Mo-based ingot. However, if air is present in the gap, the aim of suppressing oxidation is not achieved. If an inert gas is present in the gap, the encapsulating plate may bulge unnecessarily during heating. Therefore, the gas present in the gap is removed by vacuum evacuation. To prevent air from entering through a broken part of the encapsulating plate not only during heating but also during rolling, the welded portions, such as the seam, of the encapsulating plate must be free from pinholes and cracks. A steel plate may be used as the metal plate constituting the capsule, and a plate of carbon steel such as SS400 is mainly used. Such a material is low cost, and the encapsulating plate can be relatively easily welded along the seam, so that encapsulation can be achieved reliably.

Next, a description will be given of the conditions when the ingot or the capsule is rolled.

When rolling is performed at the oxygen concentration and rolling temperature of the present invention, the rolling reduction ratio per pass can be set to greater than 10% and 50% or less without difficulty. In such a case, a target plate with no edge cracking and no cracks can be manufactured at a high yield. Rolling may be performed at a rolling reduction ratio per pass of 10% or less. However, the number of required passes increases, so that the process is inefficient. Therefore, the rolling reduction ratio per pass is desirably greater than 10%. Under the conditions of the present invention, the occurrence of edge cracking and cracks can be suppressed even when the rolling reduction ratio per pass exceeds 10%.

When the rolling reduction ratio per pass exceeds 50%, edge cracking and cracks tend to occur in the Mo-based ingot. Therefore, the rolling reduction ratio per pass is set to 50% or less. When the total rolling reduction ratio is 30% or more and 95% or less, the advantages of the present invention are more effectively attained. When the total rolling reduction ratio is less than 30%, the area cannot be increased sufficiently. Therefore, the total rolling reduction ratio is set to 30% or more. When the total rolling reduction ratio exceeds 95%, edge cracking may occur in the Mo-based ingot even under the above oxygen concentration and temperature conditions. Therefore, the total rolling reduction ratio is set to 95% or less.

Under the above conditions, the Mo-based ingot is occasionally work-hardened during-rolling, and this causes an increase in the deformation resistance. In such a case, the Mo-based ingot may be reheated and held at 1150° C. or more and 1250° C. or less for 1 minute or more and 2 hours or less to soften the ingot. When the reheating temperature is lower than 1150° C., the ingot is not sufficiently softened. Therefore, the reheating temperature is desirably 1150° C. or more. When the reheating temperature exceeds 1250° C., the damage to the heating furnace increases. Therefore, the reheating temperature is preferably 1250° C. or less. When the holding time is less than 1 minute, the ingot may not be sufficiently softened. Therefore, the holding time is desirably 1 minute or more. When the holding time exceeds 2 hours, the crystal grain size increases, and this may cause a reduction in toughness. Therefore, the holding time is desirably 2 hours or less. When rolling is performed after reheating, the Mo-based ingot can be efficiently rolled by re-adjusting the temperature of the ingot to 600° C. or more and 950° C. or less.

Next, a description will be given of the step of manufacturing the Mo-based ingot to be rolled. The Mo-based ingot may be manufactured by a melting method. However, since the melting point of the material is high, it is efficient to manufacture the ingot by pressure-sintering an Mo-based powder mixture of an Mo powder and a powder of additive elements using the hot isostatic pressing (hereinafter referred to as “HIP”) method. Preferably, the Mo-based powder has a particle size of about 0.1 μm to 50 μm. For example, a powder having an average particle size of 6 μm is used. When the particle size exceeds 20 μm, the powder may not be sufficiently sintered. Therefore, the particle size of the Mo-based powder is more preferably 20 μm or less.

The powders are loaded into an HIP container. However, if the powders are pre-molded into a powder compact by press working or cold isostatic pressing before loaded into the container, the process can be performed more efficiently. Subsequently, the container is vacuum-sealed, and HIP sintering is performed under the conditions of a temperature of 1000° C. or more and 1300° C. or less and a pressure of 1000 atm or more and 2000 atm or less. The preferred relative density of the sintered product is 95% or more and 100% or less.

The concentration of oxygen contained in the ingot is mainly controlled before HIP. In particular, if the necessary amount of oxygen is caused to adhere to the powder or the pre-molded product, the oxygen concentration remains unchanged in the sintered product subjected to HIP. More specifically, when the oxygen concentration is less than 10 ppm by mass, the powder or the pre-molded product is heated in air at about 200° C. to 500° C. to allow oxygen to adsorb thereon. When the oxygen concentration is greater than 1000 ppm by mass, the powder or the pre-molded product is heated to about 200° C. to 500° C. in a hydrogen atmosphere to reductively desorb oxygen.

The average crystal grain size is controlled mainly by adjusting the HIP temperature and time but can also be controlled by applying, after HIP, special heat treatment for adjusting the temperature and time. In both cases, the higher the temperature and the longer the time, the greater the crystal grain size tends to be.

The container used in the HIP process may be used as a capsule for rolling. This improves the efficiency because the operation of removing the container can be omitted.

When the ingot plate is manufactured with the ingot covered with the encapsulating material, the encapsulating material must be removed to obtain the rolled ingot plate after rolling. In this case, the edge of the capsule may be cut by a sawing method or a water-jet method. To improve the yield, the edge must be cut and removed such that the cut portion of the rolled ingot plate is as small as possible.

The sputtering target plate is manufactured by machine grinding the rolled ingot plate to form a sputtering surface. The obtained Mo-based sputtering target plate can be suitably used for sputtering, and a preferable film can be deposited. For example, abnormal discharge is less likely to occur during sputtering, and cluster-like inclusions of foreign substances are not easily formed in the deposited thin film. In particular, with an Mo-based sputtering target plate having an oxygen concentration of 10 ppm by mass or more and 1000 ppm by mass or less and an average crystal grain size of greater than 10 μm and 50 μm or less, the number of particles formed during deposition is significantly low, and therefore abnormal discharge caused by such particles is less likely to occur.

More preferably, the oxygen concentration falls within the range of 10 ppm by mass or more and 600 ppm by mass or less, and the average crystal grain size falls within the range of greater than 10 μm and 35 μm or less. In the above ranges, the formed particles are significantly lowered in number, and abnormal discharge caused by such particles is less likely to occur.

The crystal grain size measured for the sputtering target plate is an average value determined by the line segment method. The measurement is made at measurement positions within a range of from a position where a sputtering surface will be formed after grinding to a position of one half of the thickness, the measurement positions being separated away from each other. At the measurement positions, metallographic observation is made on a surface parallel to the rolled surface, a surface parallel to the rolling direction and perpendicular to the rolled surface, and a surface perpendicular to the rolling direction and perpendicular to the rolled surface. The crystal grain sizes of the three surfaces are determined by the line segment method and then averaged.

The present inventors have found that abnormal discharge is much less likely to occur during sputtering when the Mo-based sputtering target plate having the above metallographic structure is formed such that the arithmetic mean waviness Wa measured on the sputtering surface is controlled to 0.1 μm or more and 2.0 μm or less.

The definition of the arithmetic mean waviness Wa is given in JIS B 0601-2001. More specifically, a measurement surface is cut by a plane perpendicular thereto. A waviness curve is obtained from a cross-sectional curve representing the profile of the cut section using a series of Gaussian filters with cut-off values λf and λc. The arithmetic mean waviness (Wa) is determined as follows. A section having a reference length L (=λf) in the direction of the center line is extracted from the waviness curve and represented by y=f(x). Here, the x-axis is taken along the center line of the extracted section, and the y-axis is taken along the direction of vertical magnification. The arithmetic mean waviness (Wa) is given by the following Equation 1 and has a unit of μm.

Wa=1/L×∫₀^{L}|f(x)|dx [Equation 1]

In the present invention, the sputtering surface has a surface shape having an arithmetic mean waviness (Wa) of 0.1 μm or more and 2.0 μm or less. The arithmetic mean waviness is measured according to JIS B 0601-2001 using, for example, a stylus-type three-dimensional surface roughness-shape meter, SURFCOM 575A-3D, product of Tokyo Seimitsu Co., Ltd. The stylus used has a radius of 5 μm, and the waviness curve extraction conditions are λc=2.5 mm and λf=12.5 mm.

When the sputtering surface has surface characteristics represented by the surface waviness defined above, even if particles of a particular size that appear when the average crystal grain size is greater than 10 μm and 50 μm or less are formed, such particles remain adsorbed on the sputtering surface. It is assumed that the adsorption may be due to localization of charge on the sputtering surface caused by the surface irregularities, and this may induce an electrostatic force between the particles and the target surface. However, the detail is not clear. The adsorption is considered to inhibit the formation of clusters of the particles that cause abnormal discharge, so that abnormal discharge is prevented from occurring.

It is necessary that the surface irregularities be represented by surface waviness with a relatively large wavelength. This is because the profile of such surface waviness does not disappear and is retained during sputtering, so that the adsorption force of the particles is maintained over the period of use of the target plate. When the wavelength is short, the irregularities disappear in a short time, and the adsorption force is reduced, so that abnormal discharge may occur.

When the arithmetic mean waviness Wa is 0.1 μm or more, the waviness is less likely to disappear during sputtering, and therefore the adsorption force of the particles described above is maintained for a long period of time. Therefore, the more preferred lower limit of the arithmetic mean waviness Wa is 0.2 μm.

When the arithmetic mean waviness Wa is 2.0 μm or less, a sufficient adsorption force is ensured for the particles, and therefore abnormal discharge does not easily occur. The adsorption of particles of a particular size that are formed when the average crystal grain size of the target plate is greater than 10 μm and 50 μm or less is most easily facilitated when the arithmetic mean waviness Wa is 1.5 μm or less. Therefore, the more preferred range of the arithmetic mean waviness Wa is 0.2 μm or more and 1.5 μm or less.

The main comment of the Mo-based sputtering target plate to be manufactured in the present invention is Mo, and the amount of Mo is 70 percent by mass or more. Examples of the other components include W, Nb, Ta, Cr, Co, Si, and Ti.

### EXAMPLE

Hereinafter, the present invention will be described in more detail by way of Examples.

### Example 1

Experiments for manufacturing Mo target plates by rolling were conducted using as a starting material a pure Mo powder of an average particle size of 5 μm. The Mo powder was cold-molded to produce pre-molded products having a relative density of about 60%. The pre-molded products were inserted into HIP containers made of SS400, and subsequently a process for controlling the oxygen content was performed for each container. 1500 ppm by mass of oxygen was adhering to the raw material powder. Therefore, the oxygen concentration was decreased by purging with the aid of hydrogen after the container was evacuated and then heating and reducing the powder at 300° C. The oxygen concentration decreased as the holding time increased. Therefore, the oxygen concentration was controlled by adjusting the holding time and was represented by an oxygen concentration measured for a pressure-sintered Mo ingot. The oxygen concentration was measured at an interior point at least 100 μm from the surface of the ingot.

After the process for controlling the oxygen concentration, the HIP container was evacuated with a rotary pump and an oil diffusion pump. After the degree of vacuum reached about 10^{31 2} Pa, the vacuum port and other portions were sealed with care to avoid the formation of pinholes. The obtained HIP container was placed in an HIP apparatus and subjected to pressure-sintering treatment under the conditions of 1150° C., a holding time of 2 hours, and 1200 atm. An Mo ingot of 220 mm width×700 mm length×60 mm thickness was cut from each of the obtained sintered products. The relative density of each of the ingots was 99.9%, and the oxygen concentrations of the ingots are listed in Table 1. The average crystal grain size of these ingots was 19 μm as measured by the line segment method.

Table 1 shows the measured average deformation resistance of each Mo ingot compression-deformed by 50% at the same temperature as the rolling temperature. The deformation resistance was measured for small test pieces cut from the ingot. More specifically, the deformation resistance was determined from an S—S curve measured at each deformation temperature using a working formastor testing machine. The holding time at the deformation temperature was 10 minutes, and the strain rate for compression deformation was 10/sec. The test pieces were compressed and deformed by 50%. The average deformation resistance is the average of deformation resistance at 0 to 50% deformation.

Each Mo ingot was rolled using a rolling mill after heated in an electric furnace. In the heating process, the Mo ingot was heated to 1000° C. and then held at 100.0° C. for 1 hour. The temperature of the ingot is measured at the surface of the ingot.

The rolling mill used was provided with work rolls having a diameter of 500 mmφ. The rolling direction was adjusted so as to coincide with the lengthwise direction of the ingot, and all the rolling passes were performed under the same rolling reduction load. The ingot was rolled at a total rolling reduction ratio of 50% such that the thickness of the ingot was reduced from 60 mm to 30 mm. The dimensions of the obtained rolled ingot plate were 220 mm width, 1400 mm length, and 30 mm thickness.

TABLE 1

| | | | | | | | | | Maximum | | | | | |
|---|---|---|---|---|---|---|---|---|---|---|---|---|---|---|
| | | | | | | | | | rolling | | | | | |
| | | | | | | | | | reduction | | | | | |
| | | | | | | | | | ratio | | | | | |
| | | | | | | | | | per pass | | | | | |
| | | | Deformation | | Results of rolling at total rolling | | | | at which | | | | | |
| | Ingot | | resistance | | reduction ratio of 50% | | | | no | Sputtering target | | | | |
| | | Aver- | Rolling | Average | Roll- | Rolling | | | edge | | | Arith- | | |
| | | age | defor- | defor- | ing | re- | Number | Edge | cracking | | Average | metic | | |
| | Oxygen | crystal | mation | mation | tem- | duction | of passes | crack- | and no | Oxygen | crystal | mean | Ab- | |
| | concen- | grain | temper- | re- | per- | ratio | for 50% | ing | cracks | concen- | grain | wavi- | normal | |
| | tration | size | ature | sistance | ature | per pass | rolling | during | occur | tration | size | ness | dis- | |
| No. | (ppm) | μm | (° C.) | (MPa) | (° C.) | (%) | reduction | rolling | (%) | (ppm) | μm | Wa μm | charge | Note |
| 1 | 5 | 19 | 800 | 410 | 800 | 6.7 | 10 | Yes | 6.1 | — | — | — | 0 | Comparative |
| | | | | | | | | | | | | | | Example |
| 2 | 10 | 19 | 800 | 330 | 800 | 9.4 | 7 | No | 10.9 | 10 | 19 | 0.95 | 0 | Example of |
| | | | | | | | | | | | | | | invention |
| 3 | 14 | 19 | 800 | 295 | 800 | 12.9 | 5 | No | 20.6 | 14 | 19 | 0.95 | 0 | Example of |
| | | | | | | | | | | | | | | invention |
| 4 | 30 | 19 | 800 | 260 | 800 | 12.9 | 5 | No | 29.3 | 30 | 19 | 0.95 | 0 | Example of |
| | | | | | | | | | | | | | | invention |
| 5 | 50 | 19 | 800 | 240 | 800 | 12.9 | 5 | No | 29.3 | 50 | 19 | 0.95 | 0 | Example of |
| | | | | | | | | | | | | | | invention |
| 6 | 100 | 19 | 800 | 205 | 800 | 12.9 | 5 | No | 29.3 | 100 | 19 | 0.95 | 0 | Example of |
| | | | | | | | | | | | | | | invention |
| 7 | 200 | 19 | 800 | 200 | 800 | 12.9 | 5 | No | 29.3 | 200 | 19 | 0.95 | 0 | Example of |
| | | | | | | | | | | | | | | invention |
| 8 | 400 | 19 | 800 | 220 | 800 | 12.9 | 5 | No | 20.6 | 400 | 19 | 0.95 | 0 | Example of |
| | | | | | | | | | | | | | | invention |
| 9 | 600 | 19 | 800 | 280 | 800 | 12.9 | 5 | No | 15.9 | 600 | 19 | 0.95 | 0 | Example of |
| | | | | | | | | | | | | | | invention |
| 10 | 800 | 19 | 800 | 320 | 800 | 9.4 | 7 | No | 12.9 | 800 | 19 | 0.95 | 0 | Example of |
| | | | | | | | | | | | | | | invention |
| 11 | 1000 | 19 | 800 | 350 | 800 | 8.3 | 8 | No | 10.9 | 1000 | 19 | 0.95 | 0 | Example of |
| | | | | | | | | | | | | | | invention |
| 12 | 1200 | 19 | 800 | 400 | 800 | 6.7 | 10 | Yes | 6.1 | — | — | — | — | Comparative |
| | | | | | | | | | | | | | | Example |
| 13 | 200 | 19 | 500 | 360 | 500 | 6.7 | 10 | Yes | 5.6 | — | — | — | — | Comparative |
| | | | | | | | | | | | | | | Example |
| 14 | 200 | 19 | 600 | 320 | 600 | 9.4 | 7 | No | 10.9 | 200 | 19 | 0.95 | 0 | Example of |
| | | | | | | | | | | | | | | invention |
| 15 | 200 | 19 | 700 | 230 | 700 | 12.9 | 5 | No | 29.3 | 200 | 19 | 0.95 | 0 | Example of |
| | | | | | | | | | | | | | | invention |
| 16 | 200 | 19 | 900 | 270 | 900 | 12.9 | 5 | No | 20.6 | 200 | 19 | 0.95 | 0 | Example of |
| | | | | | | | | | | | | | | invention |
| 17 | 200 | 19 | 950 | 340 | 950 | 8.3 | 8 | No | 10.9 | 200 | 19 | 0.95 | 0 | Example of |
| | | | | | | | | | | | | | | invention |
| 18 | 200 | 19 | 1000 | 380 | 1000 | 6.7 | 10 | Yes | 5.6 | — | — | — | — | Comparative |
| | | | | | | | | | | | | | | Example |
| 19 | 50 | 19 | 800 | 240 | 800 | 12.9 | 5 | No | 29.3 | 50 | 19 | 0.08 | 3 | Example of |
| | | | | | | | | | | | | | | invention |
| 20 | 50 | 19 | 800 | 240 | 800 | 12.9 | 5 | No | 29.3 | 50 | 19 | 0.10 | 1 | Example of |
| | | | | | | | | | | | | | | invention |
| 21 | 50 | 19 | 800 | 240 | 800 | 12.9 | 5 | No | 29.3 | 50 | 19 | 0.20 | 0 | Example of |
| | | | | | | | | | | | | | | invention |
| 22 | 50 | 19 | 800 | 240 | 800 | 12.9 | 5 | No | 29.3 | 50 | 19 | 0.52 | 0 | Example of |
| | | | | | | | | | | | | | | invention |
| 23 | 50 | 19 | 800 | 240 | 800 | 12.9 | 5 | No | 29.3 | 50 | 19 | 1.20 | 0 | Example of |
| | | | | | | | | | | | | | | invention |
| 24 | 50 | 19 | 800 | 240 | 800 | 12.9 | 5 | No | 29.3 | 50 | 19 | 1.50 | 0 | Example of |
| | | | | | | | | | | | | | | invention |
| 25 | 50 | 19 | 800 | 240 | 800 | 12.9 | 5 | No | 29.3 | 50 | 19 | 1.95 | 1 | Example of |
| | | | | | | | | | | | | | | invention |
| 26 | 50 | 19 | 800 | 240 | 800 | 12.9 | 5 | No | 29.3 | 50 | 19 | 2.50 | 4 | Example of |
| | | | | | | | | | | | | | | invention |

In Experimental Examples Nos. 1 to 12, the rolled state was examined at a rolling temperature of 800° C. for each of the ingots containing oxygen at different concentrations ranging from 5 to 1200 ppm by mass. The rolling temperature fell within the range of the present invention.

The oxygen concentrations of the Mo ingots of Nos. 1 and 12 were 5 ppm by mass and 1200 ppm by mass, respectively, and these concentrations are outside the range of the present invention. In these cases, the number of passes required for a 50% rolling reduction was 10 and was greater than those of Examples of the invention. The reason for the greater number of required passes than those of Examples of the invention is that the deformation resistance becomes large and therefore the rolling reduction ratio per pass is small.

Furthermore, rolling was performed at the same temperature of 800° C. but at different rolling reduction ratios per pass until the total rolling reduction ratio reached 50% to determine the maximum rolling reduction ratio per pass at which edge cracking and cracks do not occur. The maximum rolling reduction ratio per pass was 6.1%/pass for any of the oxygen concentrations. Therefore, at these oxygen concentrations, it is not expected to efficiently manufacture a target plate at a high yield.

In Nos. 2 to 11, the oxygen concentration was 10 ppm by mass to 1000 ppm by mass in the oxygen concentration range of the present invention. The number of passes required for a 50% rolling reduction was 5 for the Mo ingots having oxygen concentrations of 14 to 600 ppm by mass, and this number was the minimum value. In the other Examples of the invention, when the oxygen concentration was in the range of the present invention, the number of required passes was less than those of the Comparative Examples and was 8 or less. During the rolling process, no edge cracking and no cracks occurred. The reduction in the number of passes is because the deformation resistance is small in the range of the present invention, as shown in Table 1.

Furthermore, rolling was performed at the same temperature of 800° C. but at different rolling reduction ratios per pass until the total rolling reduction ratio reached 50% to determine the maximum rolling reduction ratio per pass at which edge cracking and cracks do not occur. The maximum rolling reduction ratio per pass was found to be greater than 10%/pass for all the oxygen concentrations. In particular, when the oxygen concentration was 30 ppm by mass to 200 ppm by mass, the maximum rolling reduction ratio per pass at which cracks do not occur reached 29.3% (a total rolling reduction ratio of 50% can be obtained in two rolling passes), and therefore a target plate can be very efficiently manufactured at a high yield.

In Experimental Examples Nos. 13 to 18 and 7, the oxygen concentrations in the ingots were the same (200 ppm by mass), and the rolled state was examined at different rolling temperatures ranging from 500 to 1000° C. The above oxygen concentration fell within the range of the present invention. The holding time of the ingots heated to 1000° C. was 1 hour.

Nos. 13 and 18 are Comparative Examples in which the rolling temperatures are 500° C. and 1000° C., respectively, being outside the range of the present invention. In both cases, the number of passes required for a 50% rolling reduction was 10 and was greater than those of Examples of the invention. This is because the deformation resistance is large and therefore the rolling reduction ratio per pass is small. In these Comparative Examples, edge cracking was found in the obtained Mo plates.

Furthermore, rolling was performed at 500° C. and 1000° C. but at different rolling reduction ratios per pass until the total rolling reduction ratio reached 50% to determine the maximum rolling reduction ratio per pass at which edge cracking and cracks do not occur. The maximum rolling reduction ratio per pass was 5.6%/pass at both temperatures. Therefore, at these rolling temperatures, it is not expected to efficiently manufacture a target plate at a high yield.

Nos. 14 to 17, 19 to 26, and 7 are Examples of the invention in which the rolling temperature falls within the range of 600° C. to 950° C. in the range of the present invention. Under the rolling temperature conditions of 700 to 900° C., the number of required passes was 5, and a 50% rolling reduction could be obtained in one half the number of required passes in the Comparative Examples. In the rest of the range of the present invention, a 50% rolling reduction could be obtained in a smaller number of passes than those in the Comparative Examples. In the range of the present invention, the deformation resistance is small, and the rolling reduction ratio per pass is large, so that the number of passes required to achieve the predetermined total rolling reduction is small. In addition, no edge cracking was found in the rolled Mo ingot plates obtained in these Examples of the invention.

Furthermore, rolling was performed in the same temperature range of 600° C. to 950° C. but at different rolling reduction ratios per pass until the total rolling reduction ratio reached 50% to determine the maximum rolling reduction ratio per pass at which edge cracking and cracks do not occur. The maximum rolling reduction ratio per pass was found to be greater than 10%/pass at all the temperatures. In particular, when the rolling temperature was 700° C. to 800° C., the maximum rolling reduction ratio per pass at which cracks do not occur reached 29.3% (a total rolling reduction ratio of 50% can be obtained in two rolling passes), and therefore a target plate can be very efficiently manufactured at a high yield.

Next, experiments were conducted using rolling mills having work rolls different in size from those used above to determine the maximum rolling reduction ratio per pass at which edge cracking and cracks do not occur. In these experiments, ingots having the same dimensions and oxygen concentration as those of No. 4 were used, and rolling mills having work roll diameters of 250φ and 1000φ were used. Attempts were made to reduce the thickness by 50% in one pass at a rolling temperature of 800° C. using work rolls of 250φ. In this case, rolling was successful without causing edge cracking and cracks. When work rolls of 1000φ were used, the maximum rolling reduction ratio at which edge cracking and cracks do not occur was 29.3%.

The Mo-based rolled ingots manufactured by the method of the present invention were subjected to mechanical surface grinding to produce sputtering target plates. The dimensions of the finished products were 210 mm length, 1350 mm length, and 27 mm thickness. A lathe and a vertical-axis rotary grinder were used for rough grinding, and the sputtering surface was finished with an Al₂O₃-based ceramic grinding wheel (grit number: #60), more specifically, using a horizontal-axis surface grinder at a peripheral speed of the grinding wheel of 1600 m/min and a sample feeding rate of 10 m/min. The direction of surface grinding was adjusted so as to coincide with the lengthwise direction of the target plate.

In the surface grinder, the uniformity of the axial rotation of the grinding wheel and the uniformity of the sample feeding rate can be changed by adjusting the grinder, and the degree of surface waviness of the finished sputtering surface was controlled by adjusting the grinder. The higher the uniformity of axial rotation of the grinding wheel and the uniformity of the sample feeding rate, the smaller the degree of surface waviness.

With the rolled ingot plates of Nos. 1, 12, 13, and 18 in which edge cracking and cracks occurred, the edge cracking and cracks were not completely removed by the grinding, and therefore target plates were not produced. The crystal grain size was measured as follows. Metallographic observation was made on a surface parallel to the rolled surface, a surface parallel to the rolling direction and perpendicular to the rolled surface, and a surface perpendicular to the rolling direction and perpendicular to the rolled surface. The crystal grain sizes of the three surfaces were determined by the line segment method and then averaged. The average crystal grain size was measured in a region 1 mm, in the thickness direction, from the sputtering surface and was 19 μm for all the target plates.

The arithmetic mean waviness Wa was measured according to JIS B 0601-2001 using a stylus-type three-dimensional surface roughness-shape meter, SURFCOM 575A-3D, product of Tokyo Seimitsu Co., Ltd. The radius of the stylus was 5 μm, and the waviness curve extraction conditions were λc=2.5 mm and λf=12.5 mm.

The measurement was made at three points located in the widthwise central portion of the target plate and 100 mm, 675 mm, and 1250 mm from one lengthwise end. The measurement was performed in the lengthwise and widthwise directions at each measurement point, and the total number of determinations was 6. The measured values of the arithmetic mean waviness Wa were weighted and averaged to give an evaluation value of the arithmetic mean waviness Wa.

In Nos. 2 to 11 and 14 to 17, the arithmetic mean waviness Wa was 0.95 μm. In Nos. 19 to 26, the arithmetic mean waviness Wa was 0.08 to 2.50 μm.

The obtained target plate was bonded to a copper-made backing plate with a brazing material and then installed in a sputtering apparatus. An Mo film having a thickness of 3.0 μm was deposited on an SiO₂ substrate using the sputtering apparatus. The sputtering conditions were a sputtering pressure of 0.4 Pa, an Ar gas flow rate of 12 sccm (standard cc(cm³)/min), and a substrate temperature of 150° C.

When the used target plates had an oxygen concentration of 50 to 200 ppm, an average crystal grain size of 19 μm, and an arithmetic mean waviness Wa of 0.10 to 1.95 μm, the number of occurrences of abnormal discharge was 1 or less, and the characteristics were found to be excellent. In particular, when the used target plates had an arithmetic mean waviness Wa of 0.20 to 1.50 μm, no abnormal discharge occurred during deposition. However, when the arithmetic mean waviness Wa was less than 0.1 μm or greater than 2.0 μm, the number of occurrences of abnormal discharge increased slightly.

As described above, it was found that, by adjusting the concentration of oxygen contained in an Mo ingot and the rolling temperature within the ranges of the present invention, an Mo sputtering target plate can be manufactured more efficiently at a higher yield than conventional products. It was also found that, when an Mo sputtering target plate has an oxygen concentration, average crystal grain size, and surface waviness adjusted within the ranges of the present invention, abnormal discharge is less likely to occur during deposition and a high quality film containing a very small amount of particles can be deposited.

### Example 2

A plurality of Mo ingot plates were manufactured under the same manufacturing conditions as those in Example No. 7 of the invention in Example 1, and experiments for examining the influence of reheating treatment on rolling were conducted. The concentration of oxygen contained in the Mo ingots was 200 ppm by mass. The oxygen concentration was measured at an interior point at least 100 μm from the surface. The average crystal grain size of the ingots measured by the line segment method was 19 μm. The dimensions of the Mo ingots were 220 mm width×1400 mm length×30 mm thickness.

First, the Mo ingot plates were reheated at temperatures of 1000 to 1300° C. and held for 1 hour. The reheating was performed in air using an electric furnace. To determine the compressive deformation resistance of each reheated ingot, small test pieces were cut from the reheated ingot, and a working formastor test was performed at the same temperature as the rolling temperature to measure an S—S curve during compression. The holding time at the deformation temperature was 10 minutes, and the strain rate for compression deformation was 10/sec. The test pieces were compressed and deformed by 50%. The average deformation resistance is the average of deformation resistance at 0 to 50% deformation. The results are shown in Table 2.

TABLE 2

| | | | | | | | | | | Maximum | | | | | |
|---|---|---|---|---|---|---|---|---|---|---|---|---|---|---|---|
| | | | | | | | | | | rolling | | | | | |
| | | | | | | | | | | reduction | | | | | |
| | | | | | | | | | | ratio | | | | | |
| | | | | | | | | | | per pass | | | | | |
| | | | | Deformation | | Results of rolling at total rolling | | | | at which | | | | | |
| | Ingot | | Re- | resistance | | reduction ratio of 50% | | | | no | Sputtering target | | | | |
| | | Aver- | heat- | Rolling | Average | Roll- | Rolling | | | edge | | | Arith- | | |
| | | age | ing | defor- | defor- | ing | re- | Number | Edge | cracking | | Average | metic | | |
| | Oxygen | crystal | tem- | mation | mation | tem- | duction | of passes | crack- | and no | Oxygen | crystal | mean | Ab- | |
| | concen- | grain | per- | temper- | re- | per- | ratio | for 50% | ing | cracks | concen- | grain | wavi- | normal | |
| | tration | size | ature | ature | sistance | ature | per pass | rolling | during | occur | tration | size | ness | dis- | |
| No. | (ppm) | μm | (°C.) | (° C.) | (MPa) | (° C.) | (%) | reduction | rolling | (%) | (ppm) | μm | Wa μm | charge | Note |
| 27 | 200 | 19 | No | 800 | 420 | 800 | 10.9 | 6 | No | 29.3 | 200 | 19 | 0.83 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 28 | 200 | 19 | 1000 | 800 | 420 | 800 | 10.9 | 6 | No | 29.3 | 200 | 25 | 0.83 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 29 | 200 | 19 | 1100 | 800 | 420 | 800 | 10.9 | 6 | No | 29.3 | 200 | 23 | 0.83 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 30 | 200 | 19 | 1150 | 800 | 360 | 800 | 12.9 | 5 | No | 50 | 200 | 23 | 0.83 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 31 | 200 | 19 | 1200 | 800 | 200 | 800 | 20.6 | 3 | No | 50 | 200 | 25 | 0.83 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 32 | 200 | 19 | 1250 | 800 | 200 | 800 | 20.6 | 3 | No | 50 | 200 | 32 | 0.83 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 33 | 200 | 19 | 1300 | 800 | 200 | 800 | 20.6 | 3 | No | 50 | 200 | 53 | 0.83 | 3 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 34 | 200 | 19 | 1200 | 500 | 380 | 500 | 10.9 | 6 | Yes | 5.6 | — | — | — | — | Com- |
| | | | | | | | | | | | | | | | par- |
| | | | | | | | | | | | | | | | ative |
| | | | | | | | | | | | | | | | Ex- |
| | | | | | | | | | | | | | | | am- |
| | | | | | | | | | | | | | | | ple |
| 35 | 200 | 19 | 1200 | 1000 | 380 | 1000 | 10.9 | 6 | Yes | 5.6 | — | — | — | — | Com- |
| | | | | | | | | | | | | | | | par- |
| | | | | | | | | | | | | | | | ative |
| | | | | | | | | | | | | | | | Ex- |
| | | | | | | | | | | | | | | | am- |
| | | | | | | | | | | | | | | | ple |

In Experimental Example No. 27, reheating was not performed. In this case, the average deformation resistance during compression-deformation at a deformation temperature of 800° C. was 420 MPa.

In Experimental Examples Nos. 28 to 33, different reheating temperature between 1000 and 1300° C. were employed, and the average deformation resistance of the reheated ingots during compression-deformation at a constant temperature of 800° C. was determined. When the reheating temperature was 1000 or 1100° C., the average deformation resistance was 420 MPa and was at the same level as that of Example No. 27 in which reheating was not performed. When the reheating temperature was 1150 to 1300° C., the average deformation resistance was smaller than that of Experimental Example No. 27. In particular, when the reheating temperature was 1200° C. or more, the amount of decrease was large, and the average deformation resistance decreased one-half.

In Comparative Examples Nos. 34 and 35, the same reheating temperature of 1200° C. was employed. After reheating, the average deformation resistance during compression deformation at a temperature of 500 or 1000° C., which are outside the range of the present invention, was determined. In these cases, although reheating was performed at 1200° C., the average deformation resistance was large (380 MPa).

Next, experiments were conducted in which an Mo ingot having a thickness of 30 mm was rolled to reduce the thickness to 15 mm. A two-stage reversible rolling mill provided with work rolls having a diameter of 500 mmφ was used. The target total rolling reduction ratio was 50%, and the target thickness was 15 mm. All the rolling passes were performed under the same rolling reduction load. The dimensions of the obtained rolled ingot plates were 220 mm width×2800 mm length×15 mm thickness.

In Example No. 27 of the invention in which reheating was not performed, the number of passes required for a 50% rolling reduction was 6. No edge cracking was found in the obtained ingot plate.

In Nos. 28 to 33, the reheating temperature was changed between 1000 and 1300° C. When the reheating temperature was 1150° C. or more, the number of passes required to achieve the predetermined total thickness reduction tended to be smaller than that of No. 27 in which reheating was not performed. In particular, when the reheating temperature was 1200° C. or more, the number of passes decreased to 3. The decrease in the number of passes is related to the decrease in deformation resistance due to reheating. When the reheating temperature exceeded 1250° C., the damage to the reheating furnace was large, causing an increase in maintenance frequency.

For Nos. 27 to 33, rolling was performed at different rolling reduction ratios per pass until the total rolling reduction ratio reached 50% to determine the maximum rolling reduction ratio per pass at which edge cracking and cracks do not occur. The maximum rolling reduction ratio per pass was greater than 10%/pass for all the temperatures. In particular, when the reheating temperature was 1150° C. to 1300° C., the maximum rolling reduction ratio per pass at which cracks do not occur reached 50% (a total rolling reduction ratio of 50% can be obtained in one rolling pass), and therefore a target plate can be very efficiently manufactured at a high yield.

In Comparative Examples Nos. 34 and 35, after reheating was performed at 1200° C., rolling was performed at a rolling temperature of 500° C. or 1000° C. In both cases, although reheating was performed, the number of passes required to achieve the predetermined total thickness reduction as large, i.e., 6, since the rolling temperature was outside the range of the present invention, and this caused edge cracking.

Rolling was performed at 500° C. and 1000° C. and at different rolling reduction ratios per pass until the total rolling reduction ratio reached 50% to determine the maximum rolling reduction ratio per pass at which edge cracking and cracks do not occur. The maximum rolling reduction ratio per pass was 5.6%/pass at both temperatures. Therefore, at these rolling temperatures, it is not expected to efficiently manufacture a target plate at a high yield.

The Mo-based rolled ingots manufactured by the method of the present invention were subjected to mechanical surface grinding to produce sputtering target plates. The dimensions of the finished products were 215 mm width, 2700 mm length, and 12 mm thickness. A lathe and a vertical-axis rotary grinder were used for rough grinding, and the sputtering surface was finished with an Al₂O₃-based ceramic grinding wheel (grit number: #60), more specifically, using a horizontal-axis surface grinder at a peripheral speed of the grinding wheel of 1800 m/min and a sample feeding rate of 15 m/min. The direction of surface grinding was adjusted so as to coincide with the lengthwise direction of the target plate.

In the surface grinder, the uniformity of the axial rotation of the grinding wheel and the uniformity of the sample feeding rate can be changed by adjusting the grinder, and the degree of surface waviness of the finished sputtering surface was controlled by adjusting the grinder. The higher the uniformity of axial rotation of the grinding wheel and the uniformity of the sample feeding rate, the smaller the degree of surface waviness.

With the rolled ingot plates of Nos. 34 and 35 in which edge cracking and cracks occurred, the edge cracking and cracks were not completely removed by the grinding, and therefore target plates were not produced. The average crystal grain size was measured at a point 1 mm, in the thickness direction, from the sputtering surface by the same method as in Example 1. In the target plates of Nos. 27 to 32, the average crystal grain size was 21 to 32 μm. In the target plate of No. 33, the average crystal grain size was 53 μm, which is greater than the preferred upper limit of 50 μm.

The arithmetic mean waviness Wa was measured according to JIS B 0601-2001 using a stylus-type three-dimensional surface roughness-shape meter, SURFCOM 575A-3D, product of Tokyo Seimitsu Co., Ltd. The radius of the stylus was 5 μm, and the waviness curve extraction conditions were λc=2.5 mm and λf=12.5 mm.

The measurement was made at three points located in the widthwise central portion of the target plate and 100 mm, 1350 mm, and 2600 mm from one lengthwise end. The measurement was performed in the lengthwise and widthwise directions at each measurement point, and the total number of determinations was 6. The measured values of the arithmetic mean waviness Wa were weighted and averaged to give an evaluation value of the arithmetic mean waviness Wa. The arithmetic mean waviness Wa was 0.83 μm for all the target plates.

The obtained target plate was bonded to a copper-made backing plate with a brazing material and then installed in a sputtering apparatus. An Mo film having a thickness of 3.0 μm was continuously deposited on an SiO₂ substrate using the sputtering apparatus. The sputtering conditions were a sputtering pressure of 0.4 Pa, an Ar gas flow rate of 12 sccm (standard cc(cm³)/min), and a substrate temperature of 150° C. When the used target plates had an oxygen concentration of 200 ppm, an average crystal grain size of 19 to 32 μm, and an arithmetic mean waviness Wa of 0.83 μm, no abnormal discharge occurred, and the characteristics were found to be excellent. However, when the average crystal grain size exceeded 50 μm, the number of occurrences of abnormal discharge increased slightly.

As described above, it was found that, by adjusting the concentration of oxygen contained in an Mo ingot, the rolling temperature, and the temperature of reheating performed during the rolling process within the ranges of the present invention, an Mo sputtering target plate can be manufactured more efficiently at a higher yield than conventional products. It was also found that, when an Mo sputtering target plate has an oxygen concentration, average crystal grain size, and surface waviness adjusted within the ranges of the present invention, abnormal discharge is less likely to occur during deposition and a high quality film containing a very small amount of particles can be deposited.

### Example 3

Experiments for manufacturing Mo-based sputtering target plates by rolling Mo-based ingots composed of Mo:W=80:20 percent by mass were conducted.

Starting raw materials were a pure Mo powder having an average particle size of 5 μm and a pure W powder having an average particle size of 8 μm. These powders were mixed well in a ball mill to produce a powder mixture. The powder mixture was molded using a cold isostatic press to produce pre-molded products having a relative density of about 60%. The pre-molded products were inserted into HIP containers made of SS41, and subsequently a process for controlling the oxygen content was performed. The oxygen concentration of the powder mixture was 3 ppm by mass, and the powder mixture was oxidized by heating to 300° C. with each container filled with air. The oxygen concentration increased as the holding time increased. Therefore, the oxygen concentration was controlled by adjusting the holding time and was represented by an oxygen concentration measured for each pressure-sintered Mo ingot.

After the process for controlling the oxygen concentration, the HIP container was evacuated with a rotary pump and an oil diffusion pump. After the degree of vacuum reached about 10⁻² Pa, the vacuum port and other portions were sealed with care to avoid the formation of pinholes. The obtained HIP container was placed in an HIP apparatus and subjected to pressure-sintering treatment under the conditions of 1250° C., a holding time of 2 hours, and 1200 atm. An Mo-based ingot of 300 mm width×400 mm length×100 mm thickness was cut from each of the obtained sintered products. The relative density of each of the ingots was 99.9%, and the oxygen concentrations of the ingots are listed in Table 3. The oxygen concentration was measured at an interior point at least 100 μm from the ingot surface.

The average crystal grain size of these ingots was 9 to 57 as measured by the line segment method.

Subsequently, each Mo-based ingot was wrapped with an SS400 steel plate having a thickness of 10 mm to form a capsule. The seam of the steel plate was joined by welding, and the welding was performed with care to avoid the formation of pinholes and cracks. A gap of the order of mm was formed between the inner surface of the capsule and the surface of the ingot. The capsule was evacuated with a rotary pump and an oil diffusion pump through the vacuum port provided in the capsule. After the degree of vacuum reached about 10⁻² Pa, the vacuum port and other portions were sealed with care to avoid the formation of pinholes. The outer dimensions of the capsule were 322 mm width×422 mm length×121 mm thickness.

Each obtained capsule was rolled, and the changes in the rolled state with oxygen concentration and rolling temperature were examined. The capsule was heated in an electric furnace in air. More specifically, the capsule was heated to 1000° C. and then held for 1 hour. Subsequently, rolling was performed at a rolling temperature selected within the range of 800° C. to 1000° C.

TABLE 3

| | | | | | | | | | Maximum | | | | | |
|---|---|---|---|---|---|---|---|---|---|---|---|---|---|---|
| | | | | | | | | | rolling | | | | | |
| | | | | | | | | | reduction | | | | | |
| | | | | | | | | | ratio | | | | | |
| | | | | | | | | | per pass | | | | | |
| | | | Deformation | | Results of rolling at total rolling | | | | at which | | | | | |
| | Ingot | | resistance | | reduction ratio of 60% | | | | no | Sputtering target | | | | |
| | | Aver- | Rolling | Average | Roll- | Rolling | | | edge | | | Arith- | | |
| | | age | defor- | defor- | ing | re- | Number | Edge | cracking | | Average | metic | | |
| | Oxygen | crystal | mation | mation | tem- | duction | of passes | crack- | and no | Oxygen | crystal | mean | Ab- | |
| | concen- | grain | temper- | re- | per- | ratio | for 60% | ing | cracks | concen- | grain | wavi- | normal | |
| | tration | size | ature | sistance | ature | per pass | rolling | during | occur | tration | size | ness | dis- | |
| No. | (ppm) | μm | (° C.) | (MPa) | (° C.) | (%) | reduction | rolling | (%) | (ppm) | μm | Wa μm | charge | Note |
| 36 | 6 | 14 | 850 | 450 | 850 | 6.3 | 14 | Yes | 4.5 | — | — | — | — | Comparative |
| | | | | | | | | | | | | | | Example |
| 37 | 10 | 14 | 850 | 370 | 850 | 8.8 | 10 | No | 10.8 | 10 | 14 | 0.57 | 0 | Example |
| | | | | | | | | | | | | | | of invention |
| 38 | 50 | 14 | 850 | 290 | 850 | 12.3 | 7 | No | 26.3 | 50 | 14 | 0.57 | 0 | Example |
| | | | | | | | | | | | | | | of invention |
| 39 | 100 | 14 | 850 | 240 | 850 | 12.3 | 7 | No | 26.3 | 100 | 14 | 0.57 | 0 | Example |
| | | | | | | | | | | | | | | of invention |
| 40 | 200 | 14 | 850 | 230 | 850 | 12.3 | 7 | No | 26.3 | 200 | 14 | 0.57 | 0 | Example |
| | | | | | | | | | | | | | | of invention |
| 41 | 400 | 14 | 850 | 260 | 850 | 12.3 | 7 | No | 16.7 | 400 | 14 | 0.57 | 0 | Example |
| | | | | | | | | | | | | | | of invention |
| 42 | 600 | 14 | 850 | 320 | 850 | 12.3 | 7 | No | 16.7 | 600 | 14 | 0.57 | 0 | Example |
| | | | | | | | | | | | | | | of invention |
| 43 | 800 | 14 | 850 | 360 | 850 | 8.8 | 10 | No | 12.3 | 800 | 14 | 0.57 | 0 | Example |
| | | | | | | | | | | | | | | of invention |
| 44 | 1000 | 14 | 850 | 390 | 850 | 8.0 | 11 | No | 10.8 | 1000 | 14 | 0.57 | 0 | Example |
| | | | | | | | | | | | | | | of invention |
| 45 | 1300 | 14 | 850 | 450 | 850 | 6.3 | 14 | Yes | 4.5 | — | — | — | — | Comparative |
| | | | | | | | | | | | | | | Example |
| 46 | 200 | 14 | 500 | 410 | 500 | 5.9 | 15 | Yes | 4.5 | — | — | — | — | Comparative |
| | | | | | | | | | | | | | | Example |
| 47 | 200 | 14 | 600 | 360 | 600 | 8.0 | 11 | No | 12.3 | 200 | 14 | 0.57 | 0 | Example |
| | | | | | | | | | | | | | | of invention |
| 48 | 200 | 14 | 700 | 260 | 700 | 10.8 | 8 | No | 20.5 | 200 | 14 | 0.57 | 0 | Example |
| | | | | | | | | | | | | | | of invention |
| 49 | 200 | 14 | 900 | 290 | 900 | 9.7 | 9 | No | 14.2 | 200 | 14 | 0.57 | 0 | Example |
| | | | | | | | | | | | | | | of invention |
| 50 | 200 | 14 | 950 | 360 | 950 | 8.8 | 10 | No | 10.8 | 200 | 14 | 0.57 | 0 | Example |
| | | | | | | | | | | | | | | of invention |
| 51 | 200 | 14 | 1000 | 420 | 1000 | 6.3 | 14 | Yes | 4.5 | — | — | — | — | Comparative |
| | | | | | | | | | | | | | | Example |
| 52 | 200 | 9 | 850 | 400 | 850 | 8.8 | 10 | No | 10.8 | 200 | 9 | 0.57 | 6 | Example |
| | | | | | | | | | | | | | | of invention |
| 53 | 200 | 11 | 850 | 380 | 850 | 8.8 | 10 | No | 10.8 | 200 | 11 | 0.57 | 0 | Example |
| | | | | | | | | | | | | | | of invention |
| 54 | 200 | 22 | 850 | 220 | 850 | 12.3 | 7 | No | 26.3 | 200 | 22 | 0.57 | 0 | Example |
| | | | | | | | | | | | | | | of invention |
| 55 | 200 | 43 | 850 | 210 | 850 | 12.3 | 7 | No | 26.3 | 200 | 43 | 0.57 | 0 | Example |
| | | | | | | | | | | | | | | of invention |
| 56 | 200 | 57 | 850 | 210 | 850 | 12.3 | 7 | No | 26.3 | 200 | 57 | 0.57 | 4 | Example |
| | | | | | | | | | | | | | | of invention |

A two-stage reversible rolling mill provided with work rolls having a diameter of 460 mmφ was used. The target total rolling reduction ratio was 60%, and the rolling was performed such that the thickness, including the thickness of the capsule, was reduced to 48 mm. The rolling direction was adjusted so as to coincide with the lengthwise direction of the capsule, and all the rolling passes were performed under the same rolling reduction load. The dimensions of the obtained rolled ingot plates were 300 mm width, 1000 mm length, and 40 mm thickness.

After the rolling process, the edge of the capsule was cut by a water-jet method, and the encapsulating plate was removed to obtain the Mo-based ingot plate. Then, the ingot plate was carefully observed to determine whether edge cracking and crack occurred.

Table 3 shows the measured average deformation resistance of each Mo-based ingot compression-deformed by 60% at the same temperature as the rolling temperature. The deformation resistance was measured for small test pieces cut from the non-rolled ingot. More specifically, the deformation resistance was determined from an S—S curve measured at each deformation temperature using a working formastor testing machine. The holding time at the heating temperature was: 60 minutes, and the strain rate for compression deformation was 10/sec. The test pieces were compressed and deformed by 60%. The average deformation resistance is the average of deformation resistance at 0 to 60% deformation.

In Experimental Examples Nos. 36 to 45, the rolled state was examined at a constant rolling temperature of 850° C. for each of the Mo-based ingots containing oxygen at different concentrations. The rolling temperature fell within the range of the present invention.

In Comparative Examples Nos. 36 and 45, the oxygen concentrations were 6 ppm by mass and 1300 ppm by mass, respectively, and these oxygen concentrations are outside the range of the present invention. In these cases, the number of passes required for a 60% rolling reduction was 14 being greater than those of Examples of the invention. The reason for the greater number of required passes than those of Examples of the invention is that the deformation resistance is large and therefore the rolling reduction ratio per pass is small. During rolling, edge cracking occurred, and therefore a high yield is not expected.

Rolling was performed at the same temperature of 850° C. but at different rolling reduction ratios per pass until the total rolling reduction ratio reached 60% to determine the maximum rolling reduction ratio per pass at which edge cracking and cracks do not occur. The maximum rolling reduction ratio per pass was 4.5%/pass for both the oxygen concentrations. Therefore, at these oxygen concentrations, it is not expected to efficiently manufacture a target plate at a high yield.

In Nos. 37 to 44, the oxygen concentration was 10 ppm by mass to 1000 ppm by mass in the oxygen concentration range of the present invention. The number of passes required for a 60% rolling reduction was 7 for the Mo-based ingots having oxygen concentrations of 50 to 600 ppm by mass, and this number was the minimum value. In these ingots, no edge cracking and no cracks were found. In the other Examples of the invention, when the oxygen concentration falls within the range of the present invention, the number of required passes was less than those of the Comparative Examples and was 11 or less. In these Inventive Examples, no edge cracking and no cracks were found after rolling. The reduction in the number of passes is because the deformation resistance is small in the range of the present invention, as shown in Table 3.

Furthermore, rolling was performed at the same temperature of 850° C. but at different rolling reduction ratios per pass until the total rolling reduction ratio reached 60% to determine the maximum rolling reduction ratio per pass at which edge cracking and cracks do not occur. The maximum rolling reduction ratio per pass was found to be greater than 10%/pass for all the oxygen concentrations. In particular, when the oxygen concentration was 50 ppm by mass to 200 ppm by mass, the maximum rolling reduction ratio per pass at which cracks do not occur reached 26.3% (a total rolling reduction ratio of 60% can be obtained in three rolling passes), and therefore a target plate can be very efficiently manufactured at a high yield.

In Experimental Examples Nos. 46 to 51 and 40, the concentrations of oxygen contained in the ingots were the same value of 200 ppm by mass, and the hot-rolled state was examined at different rolling temperatures ranging from 500 to 1000° C. The oxygen concentration fell within the range of the present invention.

Nos. 46 and 51 are Comparative Examples in which the rolling temperatures are 500° C. and 1000° C., respectively, being outside the range of the present invention. In both cases, the number of passes required for a 60% rolling reduction was 14 to 15 and was greater than those of the Examples of the invention. This is because the deformation resistance is large and therefore the rolling reduction ratio per pass is small. In these Comparative Examples, edge cracking was found in the obtained Mo plates.

Furthermore, rolling was performed at 500° C. and 1000° C. but at different rolling reduction ratios per pass until the total rolling reduction ratio reached 60% to determine the maximum rolling reduction ratio per pass at which edge cracking and cracks do not occur. The maximum rolling reduction ratio per pass was 4.5%/pass at both temperatures. Therefore, at these rolling temperatures, it is not expected to efficiently manufacture a target plate at a high yield.

Nos. 47 to 50 and 40 are Examples of the invention in which the rolling temperature falls within the range of 600° C. to 950° C. being within the range of the present invention. Under the rolling temperature conditions of 700 to 900° C., the number of required passes was 7 to 9, and the number of passes required for a 60% rolling reduction was one-half that in the Comparative Examples. In the rest of the range of the present invention, a 60% rolling reduction could be obtained in a smaller number of passes than those in the Comparative Examples. In the range of the present invention, the deformation resistance is small, and the rolling reduction ratio per pass is large, so that the number of passes required to achieve the predetermined total reduction is small. In addition, no edge cracking and no cracks were found in the Mo-based sputtering target plates obtained in these Examples of the invention.

Furthermore, rolling was performed in the same temperature range of 600° C. to 950° C. but at different rolling reduction ratios per pass until the total rolling reduction ratio reached 60% to determine the maximum rolling reduction ratio per pass at which edge cracking and cracks do not occur. The maximum rolling reduction ratio per pass was found to be greater than 10%/pass for all the temperatures. In particular, when the rolling temperature was 700° C. to 850° C., the maximum rolling reduction ratio per pass at which cracks do not occur exceeded 20%, and therefore a target plate can be very efficiently manufactured at a high yield.

Next, experiments were conducted using rolling mills having work rolls different in size from those used above to determine the maximum rolling reduction ratio per pass at which edge cracking and cracks do not occur. In these experiments, ingots having the same dimensions and oxygen concentration as those of No. 40 were used, and rolling mills having work roll diameters of 250φ and 1000φ were used. Attempts were made to reduce the thickness by 36.8% in one pass at a rolling temperature of 850° C. using work rolls of 250φ. In this case, rolling was successful without causing edge cracking and cracks. When work rolls of 1000φ were used, the maximum rolling reduction ratio at which edge cracking and cracks do not occur was 26.3%.

The Mo-based rolled ingots manufactured by the method of the present invention were subjected to mechanical surface grinding to produce sputtering target plates. The dimensions of the finished products were 285 mm length, 950 mm length, and 35 mm thickness. A lathe and a vertical-axis rotary grinder were used for rough grinding, and the sputtering surface was finished with an Al₂O₃-based ceramic grinding wheel (grit number: #60), more specifically, using a horizontal-axis surface grinder at a peripheral speed of the grinding wheel of 1400 m/min and a sample feeding rate of 9 m/rain. The direction of surface grinding was adjusted so as to coincide with the lengthwise direction of the target plate.

In the surface grinder, the uniformity of the axial rotation of the grinding wheel and the uniformity of the sample feeding rate can be changed by adjusting the grinder, and the degree of surface waviness of the finished sputtering surface was controlled by adjusting the grinder. The higher the uniformity of axial rotation of the grinding wheel and the uniformity of the sample feeding rate, the smaller the degree of surface waviness.

With the rolled ingot plates of Nos. 36, 45, 46, and 51 in which edge cracking and cracks occurred, the edge cracking and cracks were not completely removed by the grinding, and therefore target plates were not produced. The average crystal grain size was measured at a point 2 mm, in the thickness direction, from the sputtering surface by the same method as in Example 1. In the target plates of Nos. 37 to 44 and 47 to 50, the average crystal grain size was 14 μm. In the target plates of Nos. 52 to 56, the average crystal grain size was 9 to 57 μm.

The arithmetic mean waviness Wa was measured according to JIS B 0601-2001 using a stylus-type three-dimensional surface roughness-shape meter, SURFCOM 575A-3D, product of Tokyo Seimitsu Co., Ltd. The radius of the stylus was 5 μm, and the waviness curve extraction conditions were λc=2.5 mm and λf=12.5 mm.

The measurement was made at three points located in the widthwise central portion of the target plate and 50 mm, 500 mm, and 950 mm from one lengthwise end. The measurement was performed in the lengthwise and widthwise directions at each measurement point, and the total number of determinations was 6. The measured values of the arithmetic mean waviness Wa were weighted and averaged to give an evaluation value of the arithmetic mean waviness Wa. The arithmetic mean waviness Wa was 0.57 μm for all the target plates.

The obtained target plate was bonded to a copper-made backing plate with a brazing material and then installed in a sputtering apparatus. An MoW film having a thickness of 3.0 μm was continuously deposited on an SiO₂ substrate using the sputtering apparatus. The sputtering conditions were a sputtering pressure of 0.4 Pa, an Ar gas flow rate of 12 sccm (standard cc(cm³)/min), and a substrate temperature of 150° C.

When the used target plates had an oxygen concentration of 10 to 1000 ppm, an average crystal grain size of 11 to 43 μm, and an arithmetic mean waviness Wa of 0.57 μm, no abnormal discharge occurred, and the characteristics were found to be excellent. When the used target plates had average crystal grain sizes of 9 μm and 57 μm, the number of occurrences of abnormal discharge was large.

As described above, it was found that, by adjusting the concentration of oxygen contained in an Mo—W ingot and the rolling temperature within the ranges of the present invention, an Mo-based sputtering target plate can be manufactured more efficiently at a higher yield than conventional products. It was also found that, when an Mo—W sputtering target plate has an oxygen concentration, average crystal grain size, and surface waviness adjusted within the ranges of the present invention, abnormal discharge is less likely to occur during deposition and a high quality film containing a very small amount of particles can be deposited.

### Example 4

A plurality of capsules each containing an Mo—W ingot plate were manufactured under the same conditions as those in Example No. 40 of the invention in Example 3, and experiments for examining the influence of reheating treatment on rolling were conducted. The concentration of oxygen contained in the Mo-based ingot was 200 ppm by mass. The oxygen concentration was measured at an interior point at least 100 μm from the surface of the ingot. The outer dimensions of the capsules were 322 mm width×1055 mm length×48 mm thickness. The thickness of the Mo-based ingot included in the above thickness was 40 mm.

First, the Mo-based capsules were reheated at temperatures of 1000 to 1300° C. and held for 1 hour. The reheating was performed in air using an electric furnace.

To determine the compressive deformation resistance of each reheated ingot, small test pieces were cut from the ingot contained in the reheated capsule, and a working formastor test was performed at the same temperature as the rolling temperature to measure an S—S curve during compression. The holding time at the deformation temperature was 10 minutes, and the strain rate for compression deformation was 10/sec. The test pieces were compressed and deformed by 60%. The average deformation resistance is the average of deformation resistance at 0 to 60% deformation. The results are shown in Table 4.

TABLE 4

| | | | | | | | | | | Maximum | | | | | |
|---|---|---|---|---|---|---|---|---|---|---|---|---|---|---|---|
| | | | | | | | | | | rolling | | | | | |
| | | | | | | | | | | reduction | | | | | |
| | | | | | | | | | | ratio | | | | | |
| | | | | | | | | | | per pass | | | | | |
| | | | | Deformation | | Results of rolling at total rolling | | | | at which | | | | | |
| | Ingot | | Re- | resistance | | reduction ratio of 60% | | | | no | Sputtering target | | | | |
| | | Aver- | heat- | Rolling | Average | Roll- | Rolling | | | edge | | | Arith- | | |
| | | age | ing | defor- | defor- | ing | re- | Number | Edge | cracking | | Average | metic | | |
| | Oxygen | crystal | tem- | mation | mation | tem- | duction | of passes | crack- | and no | Oxygen | crystal | mean | Ab- | |
| | concen- | grain | per- | temper- | re- | per- | ratio | for 60% | ing | cracks | concen- | grain | wavi- | normal | |
| | tration | size | ature | ature | sistance | ature | per pass | rolling | during | occur | tration | size | ness | dis- | |
| No. | (ppm) | μm | (°C.) | (° C.) | (MPa) | (° C.) | (%) | reduction | rolling | (%) | (ppm) | μm | Wa μm | charge | Note |
| 57 | 200 | 14 | No | 850 | 450 | 850 | 5.9 | 15 | No | 16.7 | 200 | 14 | 0.52 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 58 | 200 | 14 | 1000 | 850 | 450 | 850 | 5.9 | 15 | No | 20.5 | 200 | 16 | 0.52 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 59 | 200 | 14 | 1100 | 850 | 450 | 850 | 5.9 | 15 | No | 26.3 | 200 | 18 | 0.52 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 60 | 200 | 14 | 1150 | 850 | 330 | 850 | 8.8 | 10 | No | 36.8 | 200 | 22 | 0.52 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 61 | 200 | 14 | 1200 | 850 | 230 | 850 | 12.3 | 7 | No | 36.8 | 200 | 25 | 0.52 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 62 | 200 | 14 | 1250 | 850 | 230 | 850 | 12.3 | 7 | No | 36.8 | 200 | 32 | 0.52 | 0 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 63 | 200 | 14 | 1300 | 850 | 240 | 850 | 12.3 | 7 | No | 36.8 | 200 | 51 | 0.52 | 2 | Ex- |
| | | | | | | | | | | | | | | | am- |
| | | | | | | | | | | | | | | | ple of |
| | | | | | | | | | | | | | | | in- |
| | | | | | | | | | | | | | | | ven- |
| | | | | | | | | | | | | | | | tion |
| 64 | 200 | 14 | 1200 | 500 | 410 | 500 | 6.3 | 14 | Yes | 4.5 | — | — | — | — | Com- |
| | | | | | | | | | | | | | | | par- |
| | | | | | | | | | | | | | | | ative |
| | | | | | | | | | | | | | | | Ex- |
| | | | | | | | | | | | | | | | am- |
| | | | | | | | | | | | | | | | ple |
| 65 | 200 | 14 | 1200 | 1000 | 430 | 1000 | 5.9 | 15 | Yes | 4.5 | — | — | — | — | Com- |
| | | | | | | | | | | | | | | | par- |
| | | | | | | | | | | | | | | | ative |
| | | | | | | | | | | | | | | | Ex- |
| | | | | | | | | | | | | | | | am- |
| | | | | | | | | | | | | | | | ple |

In Experimental Example No. 57, reheating was not performed. In this case, the average deformation resistance of the test pieces compression-deformed at 850° C. was 450 MPa.

In Experimental Examples Nos. 58 to 63, different reheating temperature between 1000 and 1300° C. were employed, and the average deformation resistance of the reheated Mo-based ingots during compression-deformation at a constant temperature of 850° C. was determined. When the reheating temperature was 1000 or 1100° C., the average deformation resistance was 450 MPa, which was at the same level as that of Example No. 57 in which reheating was not performed. When the reheating temperature was 1150 to 1300° C., the average deformation resistance was smaller than that of Experimental Example No. 57. In particular, when the reheating temperature was 1200° C. or more, the amount of decrease was large, and the average deformation resistance decreased one-half.

In Comparative Examples Nos. 64 and 65, the same reheating temperature of 1200° C. was employed. After reheating, the average deformation resistance during compression deformation under heating at a temperature of 500 or 1000° C., which are outside the range of the present invention, was determined. In these cases, although reheating was performed at 1200° C., the average deformation resistance showed 410 MPa or 430 MPa, which was large.

Next, experiments were conducted in which a capsule having a thickness of 48 mm was hot-rolled. A two-stage reversible rolling mill provided with work rolls having a diameter of 460 mmφ was used. The target total rolling reduction ratio was 60%, and the target thickness was 19.2 mm. The target thickness of the Mo-based ingot plate contained in the capsule was 16 mm. The rolling direction was adjusted so as to coincide with the lengthwise direction of the capsule, and all the rolling passes were performed under the same rolling reduction load. The dimensions of the obtained rolled ingot plates were 300 mm width×2500 mm length×16 mm thickness.

After the rolling process, the edge of the capsule was cut by a water-jet method, and the encapsulating plate was removed to obtain the Mo-based ingot plate. Then, the ingot plate was carefully observed to determine whether edge cracking and crack occurred.

In Example No. 57 of the invention in which reheating was not performed, the number of passes required for a 60% rolling reduction was 15. No edge cracking was found in the obtained ingot plate.

In Examples Nos. 58 to 63 of the invention, the reheating temperature was changed between 1000 and 1300° C., and rolling was performed at a rolling temperature of 850° C. When the reheating temperature was 1150° C. or more, the number of passes required to achieve the predetermined total rolling reduction tended to be smaller than that of No. 57 in which reheating was not performed. In particular, when the reheating temperature was 1200° C. or more, the number of passes decreased to 7. The decrease in the number of passes is related to the decrease in deformation resistance due to reheating. When the reheating temperature exceeded 1250° C., the damage to the reheating furnace was large, causing an increase in maintenance frequency.

For Nos. 57 to 63, rolling was performed at different rolling reduction ratios per pass until the total rolling reduction ratio reached 60% to determine the maximum rolling reduction ratio per pass at which edge cracking and cracks do not occur. The maximum rolling reduction ratio per pass was greater than 10%/pass for all the temperatures. In particular, when the reheating temperature was 1150° C. to 1300° C., the maximum rolling reduction ratio per pass at which cracks do not occur reached 36.8% (a total rolling reduction ratio of 60% can be obtained in two rolling passes), and therefore a target plate can be very efficiently manufactured at a high yield.

In Comparative Examples Nos. 64 and 65, after reheating was performed at 1200° C., rolling was performed at a rolling temperature of 500° C. or 1000° C. In both cases, although reheating was performed at 1200° C., the number of passes required to achieve the predetermined total rolling reduction was large, i.e., 14 and 15 since the rolling temperature was outside the range of the present invention. In addition, this caused edge cracking.

Rolling was performed at 500° C. and 1000° C. but at different rolling reduction ratios per pass until the total rolling reduction ratio reached 60% to determine the maximum rolling reduction ratio per pass at which edge cracking and cracks do not occur. The maximum rolling reduction ratio per pass was 4.5%/pass at both temperatures. Therefore, at these rolling temperatures, it is not expected to efficiently manufacture a target plate at a high yield.

The MoW rolled ingots manufactured by the method of the present invention were subjected to mechanical surface grinding to produce sputtering target plates. The dimensions of the finished products were 290 mm width, 2450 mm length, and 13 mm thickness. A lathe and a vertical-axis rotary grinder were used for rough grinding, and the sputtering surface was finished with an Al₂O₃-based ceramic grinding wheel (grit number: #60), more specifically, using a horizontal-axis surface grinder at a peripheral speed of the grinding wheel of 1500 m/min and a sample feeding rate of 12 m/min. The direction of surface-grinding was adjusted so as to coincide with the lengthwise direction of the target plate.

In the surface grinder, the uniformity of the axial rotation of the grinding wheel and the uniformity of the sample feeding rate can be changed by adjusting the grinder, and the degree of surface waviness of the finished sputtering surface was controlled by adjusting the grinder. The higher the uniformity of axial rotation of the grinding wheel and the uniformity of the sample feeding rate, the smaller the degree of surface waviness.

With the rolled ingot plates of Nos. 64 and 65 in which edge cracking and cracks occurred, the edge cracking and cracks were not completely removed by the grinding, and therefore target plates were not produced. The average crystal grain size was measured at a point 0.5 mm, in the thickness direction, from the sputtering surface by the same method as in Example 1. In the target plates of Nos. 57 to 62, the average crystal grain size was 14 to 32 μm. In the target plate of No. 63, the average crystal grain size was 51 μm, which is greater than the preferred upper limit of 50 μm.

The arithmetic mean waviness Wa was measured according to JIS B 0601-2001 using a stylus-type three-dimensional surface roughness-shape meter, SURFCOM 575A-3D, product of Tokyo Seimitsu Co., Ltd. The radius of the stylus was 5 μm, and the waviness curve extraction conditions were λc=2.5 mm and λf=12.5 mm.

The measurement was made at three points located in the widthwise central portion of the target plate and 100 mm, 1225 mm, and 2350 mm from one lengthwise end. The measurement was performed in the lengthwise and widthwise directions at each measurement point, and the total number of determinations was 6. The measured values of the arithmetic mean waviness Wa were weighted and averaged to give an evaluation value of the arithmetic mean waviness Wa. The arithmetic mean waviness Wa was 0.52 μm for all the target plates.

The obtained target plate was bonded to a copper-made backing plate with a brazing material and then installed in a sputtering apparatus. An MoW film having a thickness of 3.0 μm was continuously deposited on an SiO₂ substrate using the sputtering apparatus. The sputtering conditions were a sputtering pressure of 0.4 Pa, an Ar gas flow rate of 12 sccm (standard cc(cm³)/min), and a substrate temperature of 150° C. When the used target plates had an oxygen concentration of 200 ppm, an average crystal grain size of 14 to 32 μm, and an arithmetic mean waviness Wa of 0.52 μm, no abnormal discharge occurred, and the characteristics were found to be excellent. However, when the average crystal grain size exceeded 50 μm, the number of occurrences of abnormal discharge increased slightly.

As described above, it was found that, by adjusting the concentration of oxygen contained in an Mo—W ingot, the rolling temperature, and the temperature of reheating performed during the rolling process within the ranges of the present invention, an Mo—W sputtering target plate can be manufactured more efficiently at a higher yield than conventional products. It was also found that, when an Mo—W sputtering target plate has an oxygen concentration, average crystal grain size, and surface waviness adjusted within the ranges of the present invention, abnormal discharge is less likely to occur during deposition and a high quality film containing a very small amount of particles can be deposited.

### Example 5

Experiments for manufacturing Mo sputtering target plates by rolling were conducted using as a starting material a pure Mo powder of an average particle size of 5 μm. The Mo powder was cold-molded to produce pre-molded products having a relative density of about 60%. The pre-molded products were inserted into HIP containers made of SS400, and subsequently a process for controlling the oxygen content was performed. 1500 ppm by mass of oxygen was adhering to the raw material powder. Therefore, the oxygen concentration was decreased by purging with the aid of hydrogen after the container was evacuated and then heating and reducing the powder to 300° C. The oxygen concentration decreased as the holding time increased. Therefore, the oxygen concentration was controlled by adjusting the holding time and was represented by an oxygen concentration measured for a pressure-sintered Mo ingot. The oxygen concentration was measured at an interior point at least 100 μm from the surface of the ingot.

After the process for controlling the oxygen concentration, the HIP container was evacuated with a rotary pump and an oil diffusion pump. After the degree of vacuum reached about 10⁻² Pa, the vacuum port and other portions were sealed with care to avoid the formation of pinholes. The obtained HIP container was placed in an HIP apparatus and subjected to pressure-sintering treatment under the conditions of a heating temperature of 1100 to 1300° C., a holding time of 2 to 10 hours, and a pressure of 1200 atm. An Mo ingot of 215 mm width×780 mm length×70 mm thickness was cut from each of the obtained sintered products. The relative density of each of the ingots was 99.9%, and the oxygen concentrations of the ingots are listed in Table 5. The average crystal grain sizes of these ingots measured by the line segment method were listed in Table 5.

Table 5 shows the average deformation resistance of each Mo ingot compression-deformed by 68% at the same temperature as the rolling temperature. The deformation resistance was measured for small test pieces cut from the ingot. More specifically, the deformation resistance was determined from an S—S curve measured at each deformation temperature using a working formastor testing machine. The holding time at the deformation temperature was 10 minutes, and the strain rate for compression deformation was 10/sec. The test pieces were compressed and deformed by 68%. The average deformation resistance is the average of deformation resistance at 0 to 68% deformation.

Each Mo ingot was rolled using a rolling mill after heated in an electric furnace. In the heating process, the Mo ingot was heated to 800° C. and then held at this temperature for 2 hours. The temperature of the ingot is the temperature measured at the surface of the ingot.

The rolling mill used was provided with work rolls having a diameter of 500 mmφ. The rolling direction was adjusted so as to coincide with the lengthwise direction of the ingot, and all the rolling passes were performed under the same rolling reduction load. The ingot was rolled at a total rolling reduction ratio of 68% such that the thickness of the ingot was reduced from 70 mm to 22.4 mm. The dimensions of the obtained rolled ingot plate were 215 mm width, 2438 mm length, and 22.4 mm thickness.

TABLE 5

| | | | | | | | | | Maximum | | | | | |
|---|---|---|---|---|---|---|---|---|---|---|---|---|---|---|
| | | | | | | | | | rolling | | | | | |
| | | | | | | | | | reduction | | | | | |
| | | | | | | | | | ratio | | | | | |
| | | | | | | | | | per pass | | | | | |
| | | | Deformation | | Results of rolling at total rolling | | | | at which | | | | | |
| | Ingot | | resistance | | reduction ratio of 68% | | | | no | Sputtering target | | | | |
| | | Aver- | Rolling | Average | Roll- | Rolling | | | edge | | | Arith- | | |
| | | age | defor- | defor- | ing | re- | Number | Edge | cracking | | Average | metic | | |
| | Oxygen | crystal | mation | mation | tem- | duction | of passes | crack- | and no | Oxygen | crystal | mean | Ab- | |
| | concen- | grain | temper- | re- | per- | ratio | for 68% | ing | cracks | concen- | grain | wavi- | normal | |
| | tration | size | ature | sistance | ature | per pass | rolling | during | occur | tration | size | ness | dis- | |
| No. | (ppm) | μm | (° C.) | (MPa) | (° C.) | (%) | reduction | rolling | (%) | (ppm) | μm | Wa μm | charge | Note |
| 65 | 100 | 8.0 | 800 | 400 | 800 | 7.3 | 15 | No | 10.1 | 100 | 8.0 | 0.42 | 4 | Example of |
| | | | | | | | | | | | | | | invention |
| 66 | 100 | 10.0 | 800 | 320 | 800 | 7.3 | 15 | No | 10.1 | 100 | 10.0 | 0.42 | 2 | Example of |
| | | | | | | | | | | | | | | invention |
| 67 | 100 | 10.5 | 800 | 295 | 800 | 9.1 | 12 | No | 11.9 | 100 | 10.5 | 0.42 | 0 | Example of |
| | | | | | | | | | | | | | | invention |
| 68 | 100 | 15 | 800 | 250 | 800 | 10.1 | 10 | No | 13.3 | 100 | 15 | 0.42 | 0 | Example of |
| | | | | | | | | | | | | | | invention |
| 69 | 100 | 20 | 800 | 220 | 800 | 15 | 7 | No | 20.4 | 100 | 20 | 0.42 | 0 | Example of |
| | | | | | | | | | | | | | | invention |
| 70 | 100 | 25 | 800 | 200 | 800 | 15 | 7 | No | 20.4 | 100 | 25 | 0.42 | 0 | Example of |
| | | | | | | | | | | | | | | invention |
| 71 | 100 | 40 | 800 | 180 | 800 | 15 | 7 | No | 20.4 | 100 | 40 | 0.42 | 0 | Example of |
| | | | | | | | | | | | | | | invention |
| 72 | 100 | 50 | 800 | 180 | 800 | 15 | 7 | No | 20.4 | 100 | 50 | 0.42 | 0 | Example of |
| | | | | | | | | | | | | | | invention |
| 73 | 100 | 60 | 800 | 180 | 800 | 15 | 7 | Yes | 10.1 | 100 | 60 | 0.42 | 4 | Example of |
| | | | | | | | | | | | | | | invention |

In Experimental Examples Nos. 65 to 73, the concentrations of oxygen contained in the ingots were the same value of 100 ppm by mass, and the rolled state was examined at a rolling temperature of 800° C. and different average crystal grain sizes. The rolling temperature fell within the range of the present invention.

The average crystal grain sizes of the Mo ingots of Nos. 65 and 66 were 8.0 μm and 10.0 μm, respectively, and these are outside the preferred range of the present invention. In these cases, the number of passes required for a 68% rolling reduction was 15 and was greater than those of Examples of the invention. The reason for the greater number of required passes than those of Examples of the invention is that the deformation resistance is large and therefore the rolling reduction ratio per pass is small.

Furthermore, rolling was performed at the same temperature of 800° C. but at different rolling reduction ratios per pass until the total rolling reduction ratio reached 68% to determine the maximum rolling reduction ratio per pass at which edge cracking and cracks do not occur. The maximum rolling reduction ratio per pass was 10.1%/pass for all the oxygen concentrations.

In Nos. 67 to 72, the average crystal grain size was 10.5 to 50 μm, which fell within the preferred range of the present invention. In these cases, the number of passes required for a 68% rolling reduction was 7 to 12 for the Mo ingots having a crystal grain size of 10.5 to 50 μm. During the rolling process, no edge cracking and no cracks were formed. The reduction in the number of passes is because the deformation resistance is small in the range of the present invention, as shown in Table 5.

Furthermore, rolling was performed at the same temperature of 800° C. but at different rolling reduction ratios per pass until the total rolling reduction ratio reached 68% to determine the maximum rolling reduction ratio per pass at which edge cracking and cracks do not occur. The maximum rolling reduction ratio per pass was found to be greater than 10%/pass for all the crystal grain sizes. In particular, when the crystal grain size was greater than 10 μm and 50 μm or less, the maximum rolling reduction ratio per pass at which cracks do not occur reached 11.9 to 20.4%, and therefore a target plate can be very efficiently manufactured at a high yield.

In No. 73, the average crystal grain size was 60 μm, which is outside the preferred range of the present invention. In this case, the number of passes required for a 68% rolling reduction was 7 as in other Examples of the invention. However, a small amount of edge cracking was found in the obtained Mo plate. Rolling was performed at different rolling reduction ratios per pass until the total rolling reduction ratio reached 68% to determine the maximum rolling reduction ratio per pass at which edge cracking and cracks do not occur. The maximum rolling reduction ratio per pass was 10.1%/pass.

Next, experiments were conducted using rolling mills having work rolls different in size from those used above to determine the maximum rolling reduction ratio per pass at which edge cracking and cracks do not occur. In these experiments, ingots having the same dimensions and oxygen concentration as those of No. 69 were used, and rolling mills having work roll diameters of 250φ and 1000φ were used. Attempts were made to reduce the thickness by 20.4% in one pass at a rolling temperature of 800° C. using work rolls of 250φ. In this case, rolling was successful without causing edge cracking and cracks. When work rolls of 1000φ were used, the maximum rolling reduction ratio at which edge cracking and cracks do not occur was 20.4%.

The Mo-based rolled ingots manufactured by the method of the present invention were subjected to mechanical surface grinding to produce sputtering target plates. The dimensions of the finished products were 210 mm width, 2,400 mm length, and 20 mm thickness. A lathe and a vertical-axis rotary grinder were used for rough grinding, and the sputtering surface was finished with an Al₂O₃-based ceramic grinding wheel (grit number: #60), more specifically, using a horizontal-axis surface grinder at a peripheral speed of the grinding wheel of 1400 m/min and a sample feeding rate of 10 m/min. The direction of surface grinding was adjusted so as to coincide with the lengthwise direction of the target plate.

In the surface grinder, the uniformity of the axial rotation of the grinding wheel and the uniformity of the sample feeding rate can be changed by adjusting the grinder, and the degree of surface waviness of the finished sputtering surface was controlled by adjusting the grinder. The higher the uniformity of axial rotation of the grinding wheel and the uniformity of the sample feeding rate, the smaller the degree of surface waviness.

With the rolled ingot plate of No. 73 in which edge cracking and cracks occurred, the edge cracking and cracks could be removed by the grinding, and therefore a finished target plate was produced. The average crystal grain size was measured at a point 3 mm, in the thickness direction, from the sputtering surface by the same method as in Example 1. In the target plates of Nos. 67 to 72, the average crystal grain size was 10.5 to 50 μm. In the target plates of Nos. 65 and 66, the average crystal grain size was 10.0 μm or less (8.0 or 10.0 μm). In the target plate of No. 73, the average crystal grain size was 60 μm, which is greater than the preferred upper limit of the present invention of 50 μm.

The arithmetic mean waviness Wa was measured according to JIS B 0601-2001 using a stylus-type three-dimensional surface roughness-shape meter, SURFCOM 575A-3D, product of Tokyo Seimitsu Co., Ltd. The radius of the stylus was 5 μm, and the waviness curve extraction conditions were λc=2.5 mm and λf=12.5 mm.

The measurement was made at three points located in the widthwise central portion of the target plate and 100 mm, 1200 mm, and 2300 mm from one lengthwise end. The measurement was performed in the lengthwise and widthwise directions at each measurement point, and the total number of determinations was 6. The measured values of the arithmetic mean waviness Wa were weighted and averaged to give an evaluation value of the arithmetic mean waviness Wa. The arithmetic mean waviness Wa was 0.42 μm for all the target plates.

The obtained target plate was bonded to a copper-made backing plate with a brazing material and then installed in a sputtering apparatus. An Mo film having a thickness of 3.0 μm was deposited on an SiO₂ substrate using the sputtering apparatus. The sputtering conditions were a sputtering pressure of 0.4 Pa, an Ar gas flow rate of 12 sccm (standard cc(cm³)/min), and a substrate temperature of 150° C. When the used target plates had an oxygen concentration of 100 ppm, an average crystal grain size of 10.5 to 50 μm, and an arithmetic mean waviness Wa of 0.42 μm, no abnormal discharge occurred, and the characteristics were found to be excellent. However, when the average crystal grain size was 10.0 μm or less or greater than 50 μm, the number of occurrences of abnormal discharge increased slightly.

As described above, it was found that, by adjusting the concentration of oxygen contained in an Mo ingot, the rolling temperature, and the temperature of reheating performed during the rolling process within the ranges of the present invention, an Mo sputtering target plate can be manufactured more efficiently at a higher yield than conventional products. It was also found that, when an Mo sputtering target plate has an oxygen concentration, average crystal grain size, and surface waviness adjusted within the ranges of the present invention, abnormal discharge is less likely to occur during deposition and a high quality film containing a very small amount of particles can be deposited.

### INDUSTRIAL APPLICABILITY

The Mo target plates obtained in accordance with the present invention are high quality and low cost. Therefore, the present invention is applicable to a sputtering target plate for electrode members constituting liquid crystal devices and the like.

### BRIEF DESCRIPTION OF THE DRAWINGS

FIG. 1 shows the oxygen concentration dependence of the average deformation resistance of Mo ingots at a deformation temperature of 800° C.

FIG. 2 shows the deformation temperature dependence of the average deformation resistance of Mo ingots having oxygen concentrations of 5 ppm (Comparative Example) and 200 ppm (Example of the invention).

FIG. 3 shows the average crystal grain size dependence of the average deformation resistance of Mo ingots having oxygen concentrations of 100 ppm.

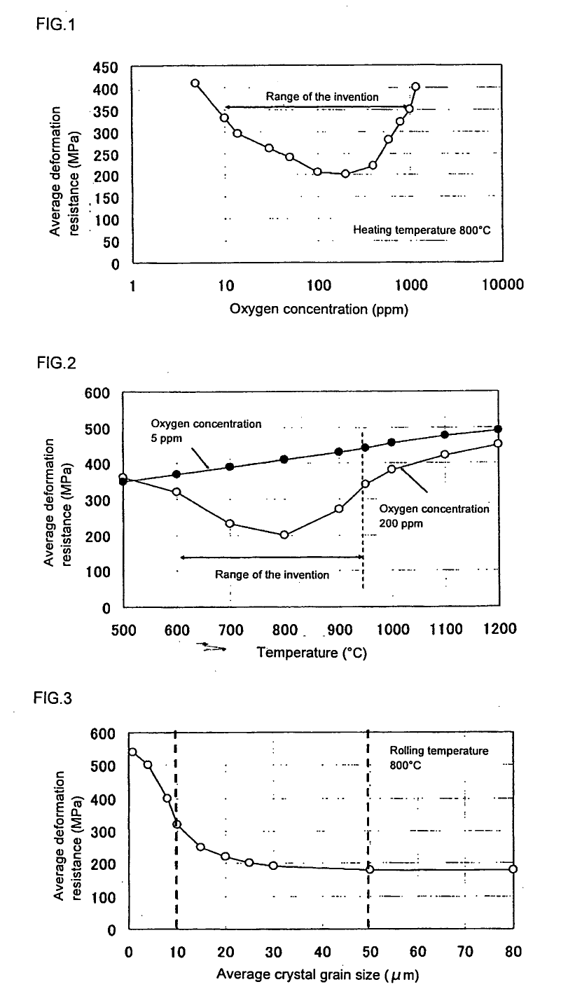

1. A method for manufacturing an Mo-based sputtering target plate from an Mo-based ingot, the method comprising the successive steps of: manufacturing the Mo-based ingot in which an oxygen concentration is controlled to 10 ppm by mass or more and 1000 ppm by mass or less; and heating and rolling the Mo-based ingot at a rolling temperature of 600° C. or more and 950° C. or less.

2. A method for manufacturing an Mo-based sputtering target plate from an Mo-based ingot, the method comprising the successive steps of: manufacturing the Mo-based ingot in which an oxygen concentration is controlled to 10 ppm by mass or more and 1000 ppm by mass or less; wrapping the Mo-based ingot with a metal plate to form a capsule and evacuating and vacuum-sealing the capsule; heating and rolling the capsule at a rolling temperature of 600° C. or more and 950° C. or less; and removing the Mo-based plate from the capsule.

3. The method for manufacturing an Mo-based sputtering target plate according to claim 1 or 2, wherein, in the step of manufacturing the Mo-based ingot, an average crystal grain size of the Mo-based ingot is controlled to more than 10 μM and 50 μm or less.

4. The method for manufacturing an Mo-based sputtering target plate according to claim 1 or 2, wherein, in the step of rolling, a rolling reduction ratio per pass is more than 10% and 50% or less, and a total rolling reduction ratio is 30% or more and 95% or less.

5. The method for manufacturing an Mo-based sputtering target plate according to claim 1 or 2, wherein the step of rolling comprises the step of reheating at a reheating temperature of 1150° C. or more and 1250° C. or less and holding at the reheating temperature for 1 minute or more and 2 hours or less.

6. The method for manufacturing an Mo-based sputtering target plate according to claim 1 or 2, wherein the Mo-based ingot is obtained by pressure-sintering a raw Mo-based powder having a particle size of 20 μm or less by a hot isostatic pressing method.

7. The method for manufacturing an Mo-based sputtering target plate according to claim 2, wherein the metal plate is a steel plate.

8. The method for manufacturing an Mo-based sputtering target plate according to claim 1 or 2, further comprising, after the step of rolling, the step of forming a sputtering surface by mechanical surface grinding.

9. An Mo-based sputtering target plate having an oxygen concentration of 10 ppm by mass or more and 1000 ppm by mass or less and an average crystal grain size of more than 10 μm and 50 μm or less.

10. The Mo-based sputtering target plate according to claim 9, having a sputtering surface of an arithmetic mean waviness (Wa) of 0.1 μm or more and 2.0 μm or less.
